(19) United States
(12) Patent Application Publication
(10) Pub. No.: US 2025/0220972 A1
(43) Pub. Date: Jul. 3, 2025

(54) SEMICONDUCTOR DEVICE

(71) Applicant: Semiconductor Energy Laboratory Co., Ltd., Atsugi-shi, Kanagawa-ken (JP)

(72) Inventors: Masami JINTYOU, Shimotsuga (JP); Yukinori SHIMA, Tatebayashi (JP); Junichi KOEZUKA, Tochigi (JP); Shinya SASAGAWA, Isehara (JP)

(21) Appl. No.: 18/852,619

(22) PCT Filed: Mar. 31, 2023
(86) PCT No.: PCT/IB2023/053222

§ 371 Date: Sep. 30, 2024

(30) Foreign Application Priority Data
Apr. 15, 2022 (JP) 2022-067447

(51) Int. Cl. H10D 30/67

(52) U.S. Cl. CPC H10D 30/6739; H10D 30/6704; H10D 30/6755

(57) ABSTRACT

A transistor that can be miniaturized is provided. A transistor that occupies a small area is provided. A transistor with a small channel length is provided. A semiconductor device includes a first insulating layer, a semiconductor layer, a gate insulating layer, a gate electrode, a first electrode, a second electrode, and a first conductive layer. A side surface of the first insulating layer is positioned over the first electrode. The second electrode is positioned over the first insulating layer. The semiconductor layer is in contact with the first electrode, the side surface of the first insulating layer, and the second electrode. The gate insulating layer includes a portion facing the side surface with the semiconductor layer therebetween. The gate electrode includes a portion facing the side surface with the gate insulating layer and the semiconductor layer therebetween. The first conductive layer is in contact with the gate electrode, includes a portion facing the side surface with the gate electrode, the gate insulating layer, and the semiconductor layer therebetween, and includes a portion thicker than the gate electrode.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display device including a semiconductor device.

Note that one embodiment of the present invention is not limited to the above technical field. Examples of the technical field of one embodiment of the present invention disclosed in this specification and the like include a semiconductor device, a display device, a light-emitting apparatus, a power storage device, a storage device, an electronic device, a lighting device, an input device, an input/output device, a driving method thereof, and a manufacturing method thereof. A semiconductor device refers to any device that can function by utilizing semiconductor characteristics.

### BACKGROUND ART

Miniaturization of transistors has been required. For example, in the case of application to a high-resolution display device, the reduction in the area occupied by a transistor has been considered in order to reduce the pixel size.

In recent years, the resolution of display panels has been increased. For example, as a device requiring high-resolution display panels, a device for virtual reality (VR) or augmented reality (AR) have been actively developed in recent years. For a high-resolution display panel, a light-emitting element such as an organic EL (Electro Luminesce) element or a light-emitting diode (LED) is mainly used.

Patent Document 1 discloses a high-resolution display device using an organic EL device (also referred to as an organic EL element).

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a transistor that can be miniaturized. Another object is to provide a transistor whose channel length can be reduced. Another object is to provide a transistor that occupies a small area. Another object is to provide a semiconductor device with reduced wiring resistance. Another object is to provide a display device that can easily achieve higher resolution. Another object is to provide a transistor and a semiconductor device which have high reliability.

An object of one embodiment of the present invention is to provide a transistor, a display device, and an electronic device each having a novel structure. An object of one embodiment of the present invention is to at least alleviate at least one of problems of the conventional technique.

Note that the description of these objects does not preclude the existence of other objects. Note that one embodiment of the present invention does not necessarily achieve all these objects. Note that objects other than these can be derived from the description of the specification, the drawings, the claims, and the like.

### Means for Solving the Problems

One embodiment of the present invention is a semiconductor device including a first insulating layer, a semiconductor layer, a gate insulating layer, a gate electrode, a first electrode, a second electrode, and a first conductive layer. A side surface of the first insulating layer is positioned over the first electrode. The second electrode is positioned over the first insulating layer. The semiconductor layer is in contact with the first electrode, the side surface of the first insulating layer, and the second electrode. The gate insulating layer includes a portion facing the side surface of the first insulating layer with the semiconductor layer therebetween. The gate electrode includes a portion facing the side surface of the first insulating layer with the gate insulating layer and the semiconductor layer therebetween. The first conductive layer is in contact with the gate electrode, includes a portion facing the side surface of the first insulating layer with the gate electrode, the gate insulating layer, and the semiconductor layer therebetween, and includes a portion thicker than the gate electrode.

Another embodiment of the present invention is a semiconductor device including a first insulating layer, a semiconductor layer, a gate insulating layer, a gate electrode, a first electrode, a second electrode, and a first conductive layer. The first insulating layer has an opening. A side surface of the first insulating layer in the opening is positioned over the first electrode. The second electrode is positioned over the first insulating layer. The semiconductor layer, the gate insulating layer, the gate electrode, and the first conductive layer each include a portion positioned inside the opening. The semiconductor layer is in contact with the first electrode, the side surface of the first insulating layer, and the second electrode. The gate insulating layer includes a portion facing the side surface of the first insulating layer with the semiconductor layer therebetween. The gate electrode includes a portion facing the side surface of the first insulating layer with the gate insulating layer and the semiconductor layer therebetween. The first conductive layer is in contact with the gate electrode, includes a portion facing the side surface of the first insulating layer with the gate electrode, the gate insulating layer, and the semiconductor layer therebetween, and includes a portion thicker than the gate electrode.

Another embodiment of the present invention is a semiconductor device including a first insulating layer, a semiconductor layer, a gate insulating layer, a gate electrode, a first electrode, a second electrode, and a first conductive layer. The first insulating layer has a slit. A side surface of the first insulating layer in the slit is positioned over the first electrode. The second electrode is positioned over the first insulating layer. The semiconductor layer, the gate insulating layer, the gate electrode, and the first conductive layer each include a portion positioned inside the slit. The semiconductor layer is in contact with the first electrode, the side surface of the first insulating layer, and the second electrode. The gate insulating layer includes a portion facing the side surface of the first insulating layer with the semiconductor layer therebetween. The gate electrode includes a portion facing the side surface of the first insulating layer with the gate insulating layer and the semiconductor layer therebetween. The first conductive layer is in contact with the gate electrode, includes a portion facing the side surface of the first insulating layer with the gate electrode, the gate insulating layer, and the semiconductor layer therebetween, and includes a portion thicker than the gate electrode.

In any of the above, a second insulating layer is preferably further included. In that case, a top surface of the first conductive layer is preferably substantially level with a top surface of the second insulating layer.

In any of the above, the semiconductor layer preferably includes a metal oxide. In that case, the first electrode preferably includes a metal oxide having a composition different from that of the semiconductor layer.

In addition, in the above, a second conductive layer is preferably included. In that case, the first electrode preferably includes a portion in contact with a top surface of the second conductive layer. The second conductive layer preferably contains a metal or an alloy.

In any of the above, the semiconductor layer preferably includes a first portion in contact with a top surface of the first electrode, a second portion in contact with the side surface of the first insulating layer, and a third portion positioned over the first insulating layer. In that case, the thickness of the second portion is preferably smaller than those of the first portion and the third portion.

In any of the above, a portion where an angle formed between the side surface of the first insulating layer and the top surface of the first electrode is greater than or equal to 90° and less than or equal to 120° is preferably included.

In any of the above, the side surface of the first insulating layer preferably has an uneven shape.

In any of the above, the semiconductor layer is preferably in contact with a top surface of the second electrode. The semiconductor layer preferably includes a metal oxide. The second electrode preferably includes a metal oxide having a composition different from that of the semiconductor layer.

In addition, in the above, a third conductive layer is preferably included. At this time, the second electrode preferably includes a portion in contact with the third conductive layer. Furthermore, the third conductive layer preferably contains a metal or an alloy.

### Effect of the Invention

According to one embodiment of the present invention, a transistor that can be miniaturized can be provided. Alternatively, a transistor whose channel length can be reduced can be provided. Alternatively, a transistor that occupies a small area can be provided. Alternatively, a semiconductor device with reduced wiring resistance can be provided. Alternatively, a display device that can easily achieve higher resolution can be provided. Alternatively, a transistor and a semiconductor device which have high reliability can be provided.

According to one embodiment of the present invention, a transistor, a display device, or an electronic device each having a novel structure can be provided. According to one embodiment of the present invention, at least one of problems of the conventional technique can be at least alleviated.

Note that the description of these effects does not preclude the existence of other effects. Note that one embodiment of the present invention does not need to have all these effects. Note that effects other than these can be derived from the description of the specification, the drawings, the claims, and the like.

### BRIEF DESCRIPTION OF THE DRAWINGS

FIG. 1A to FIG. 1C are diagrams illustrating a structure example of a semiconductor device.

FIG. 2A and FIG. 2B are diagrams illustrating structure examples of a semiconductor device.

FIG. 3A to FIG. 3D are diagrams illustrating structure examples of a semiconductor device.

FIG. 4A and FIG. 4B are diagrams illustrating structure examples of a semiconductor device.

FIG. 5A and FIG. 5B are diagrams illustrating structure examples of a semiconductor device.

FIG. 6A and FIG. 6B are diagrams illustrating structure examples of a semiconductor device.

FIG. 7A and FIG. 7B are diagrams illustrating structure examples of a semiconductor device.

FIG. 8 is a diagram illustrating a structure example of a semiconductor device.

FIG. 9A to FIG. 9H are diagrams illustrating structure examples of a semiconductor device.

FIG. 10A1, FIG. 10A2, and FIG. 10B1, and FIG. 10B2 are diagrams illustrating structure examples of a semiconductor device.

FIG. 11A1, FIG. 11A2, FIG. 11B1, and FIG. 11B2 are diagrams illustrating structure examples of a semiconductor device.

FIG. 12A1, FIG. 12A2, FIG. 12B1, FIG. 12B2, FIG. 12C1, and FIG. 12C2 are diagrams illustrating a manufacturing method for a semiconductor device.

FIG. 13A1, FIG. 13A2, FIG. 13B1, FIG. 13B2, FIG. 13C1, and FIG. 13C2 are diagrams illustrating a manufacturing method for a semiconductor device.

FIG. 14A and FIG. 14B are diagrams illustrating a structure example of a semiconductor device.

FIG. 15A and FIG. 15B are diagrams illustrating a structure example of a display device.

FIG. 16 is a diagram illustrating a structure example of a display device.

FIG. 17 is a diagram illustrating a structure example of a display device.

FIG. 18 is a diagram illustrating a structure example of a display device.

FIG. 19A to FIG. 19C are diagrams illustrating a structure example of a display device.

FIG. 20A and FIG. 20B are diagrams illustrating structure examples of display devices.

FIG. 21A to FIG. 21D are diagrams illustrating structure examples of electronic devices.

FIG. 22A to FIG. 22F are diagrams illustrating structure examples of electronic devices.

FIG. 23A to FIG. 23G are diagrams illustrating structure examples of electronic devices.

### MODE FOR CARRYING OUT THE INVENTION

Embodiments are described below with reference to the drawings. Note that the embodiments can be implemented with many different modes, and it will be readily understood by those skilled in the art that modes and details thereof can be changed in various ways without departing from the spirit and scope thereof. Therefore, the present invention should not be construed as being limited to the description of embodiments below.

Note that in the structures of the invention described below, the same reference numerals are used in common for the same portions or portions having similar functions in different drawings, and repeated description thereof is omitted. The same hatching pattern is applied to portions having similar functions, and the portions are not especially denoted by reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification and the like are used in order to avoid confusion among components and do not limit the number of components.

A transistor is a kind of semiconductor element and can achieve a function of amplifying a current or a voltage, a switching operation for controlling conduction or non-conduction, and the like. An IGFET (Insulated Gate Field Effect Transistor) and a thin film transistor (TFT) are in the category of a transistor in this specification.

Functions of a “source” and a “drain” are sometimes switched when a transistor of opposite polarity is used or when the direction of current is changed in circuit operation, for example. Therefore, the terms “source” and “drain” can be switched in this specification.

In this specification and the like, one of a source and a drain of a transistor is referred to as a “first electrode” and the other of the source and the drain is referred to as a “second electrode” in some cases. Note that a gate is also referred to as a “gate” or a “gate electrode”.

In this specification and the like, the expression “electrically connected” includes the case where components are connected through an “object having any electric function”. Here, there is no particular limitation on the “object having any electric function” as long as electric signals can be transmitted and received between components that are connected through the object. Examples of the “object having any electric function” include a switching element such as a transistor, a resistor, a coil, a capacitor, and other elements with a variety of functions as well as an electrode and a wiring.

Note that in this specification and the like, the expression “top surface shapes are substantially the same” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned inward from the lower layer or the upper layer is positioned outward from the lower layer; such a case is also represented by the expression “top surface shapes are substantially the same”. Note that in this specification and the like, the top surface shape of a component means the outline of the component in a plan view. A plan view means a view to observe the component from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacking order (or a formation order) of a stacked body or the like is described, even in the case where a surface on which the stacked body is provided (e.g., a formation surface, a support surface, an adhesion surface, or a planar surface) is positioned above the stacked body in the drawings, the direction and the opposite direction are expressed using “under” and “over”, respectively, in some cases.

### Embodiment 1

This embodiment describes structure examples of a transistor, which is an example of a semiconductor device of one embodiment of the present invention, and a manufacturing method thereof.

The transistor of one embodiment of the present invention includes a semiconductor layer, a gate insulating layer, a gate electrode, a first electrode, and a second electrode. The first electrode functions as one of a source electrode and a drain electrode, and the second electrode functions as the other of the source electrode and the drain electrode.

The second electrode is provided over the first electrode. Between the first electrode and the second electrode, an insulating layer functioning as a spacer is provided. An opening reaching the first electrode or a slit (groove) is provided in the insulating layer, and the semiconductor layer is provided in contact with the first electrode, the second electrode, and a side wall (also referred to as a side surface) of the insulating layer in the opening or a side wall of the slit. The gate insulating layer and the gate electrode are provided to cover the semiconductor layer.

In the transistor having the above structure, the source electrode and the drain electrode are positioned at different heights, so that the current flowing through the semiconductor layer flows in the height direction. In other words, it can also be said that the channel length direction includes a height (vertical) direction component, so that one embodiment of the present invention can also be referred to as a vertical transistor, a vertical-channel transistor, or the like.

In the above transistor, since the source electrode, the semiconductor layer, and the drain electrode can be provided to overlap with each other, the area occupied by the transistor can be dramatically reduced as compared with a so-called planar transistor in which a semiconductor layer is positioned over a flat surface.

Moreover, since the channel length of the transistor can be precisely controlled by the thickness of the insulating layer, a variation in the channel length can be made extremely reduced as compared with that of a planar transistor. Furthermore, by reducing the thickness of the insulating layer, a transistor with an extremely short channel length can be manufactured. For example, a transistor with a channel length of less than or equal to 2 m, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm and greater than or equal to 5 nm, greater than or equal to 7 nm, or greater than or equal to 10 nm can be manufactured. Therefore, a transistor with an extremely short channel length that could not be achieved with a conventional light-exposure apparatus for mass production of flat panel displays (the minimum line width: approximately 2 am or approximately 1.5 μm, for example) can be achieved. Moreover, a transistor with a channel length less than 10 nm can also be achieved without using an extremely expensive light-exposure apparatus used in the latest LSI technology.

The channel length of the transistor can be controlled not only by the thickness of the insulating layer but also by the shape of the insulating layer. For example, in the case where a side surface of the insulating layer is inclined upward, the channel length can be made larger than that of the case where the insulating layer has a vertical side surface. Furthermore, in the case where the side surface of the insulating layer has an uneven shape, the channel length can be made larger than that of the case where the insulating layer has a flat side surface.

For the semiconductor layer, a metal oxide having semiconductor characteristics (also referred to as an oxide semiconductor) is particularly preferably used so that both high performance and high productivity can be achieved. In particular, an oxide semiconductor having crystallinity is further preferably used so that high reliability can be given.

In the case where the transistor is provided using the opening provided in the insulating layer, the inner diameter of the opening corresponds to the channel width of the transistor. The smaller the diameter of the opening is, the more minutely the transistor can be manufactured. Meanwhile, since the semiconductor layer, the gate insulating layer, and the gate electrode are provided in the opening, the thicknesses of these components are preferably sufficiently smaller than the diameter of the opening (e.g., less than or equal to one-tenth of the diameter of the opening).

Meanwhile, since a thin gate electrode has increased resistance, the conductive layer (the first conductive layer) functioning as a wiring is preferably used separately from the gate electrode. In that case, the first conductive layer and the gate electrode are preferably connected to each other at a position overlapping with the opening provided in the insulating layer. Thus, a connection portion between the first conductive layer and the gate electrode and the transistor can be positioned to overlap with each other. The first conductive layer is preferably provided to fill a depressed portion on the surface of the gate electrode due to the opening in the insulating layer. Thus, the area where the gate electrode and the first conductive layer are in contact with each other can be increased and the contact resistance therebetween can be reduced.

In the case where an oxide semiconductor is used for the semiconductor layer, when a film including the oxide semiconductor (an oxide semiconductor film) is formed over the first electrode, part of the first electrode is oxidized to have resistance increased, so that the contact resistance between the semiconductor layer and the first electrode is increased or electrical conduction therebetween cannot be achieved in some cases. Therefore, for the first electrode, a conductive material that is less likely to be oxidized (e.g., a metal, an alloy, or a metal nitride), a conductive material that maintains low electric resistance even after being oxidized, or an oxide conductive material is preferably used.

Meanwhile, in the case where the conductive material that is less likely to be oxidized, the conductive material that maintains low electric resistance even after being oxidized, or the oxide conductive material, the conductivity is not sufficient in some cases. Therefore, a second conductive layer electrically connected to the first electrode is preferably provided. In that case, the second conductive layer is preferably positioned below the first electrode. Furthermore, the second conductive layer and the first electrode are preferably connected to each other at a position overlapping with the opening provided in the insulating layer. Thus, a connection portion between the first electrode and the second conductive layer and the transistor can be positioned to overlap with each other.

More specific examples are described below with reference to drawings.

### Structure Example 1

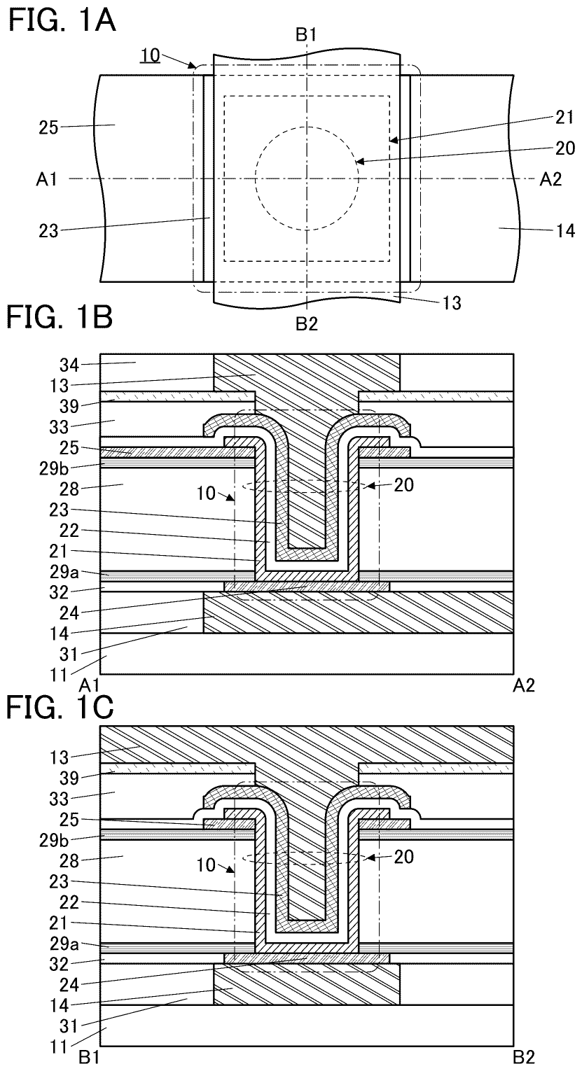

FIG. 1A is a schematic top view of a transistor 10. FIG. 1B and FIG. 1C illustrate schematic cross-sectional views taken along the cutting line A1-A1 and the cutting line B1-B2 in FIG. 1A, respectively. Note that some components (e.g., an insulating layer) are not illustrated in the schematic top view for easy viewing.

The transistor 10 is provided over a substrate 11 and includes a semiconductor layer 21, an insulating layer 22, a conductive layer 23, a conductive layer 24, and a conductive layer 25. Part of the insulating layer 22 functions as a gate insulating layer, part of the conductive layer 23 functions as a gate electrode, part of the conductive layer 24 functions as one of a source electrode and a drain electrode, and part of the conductive layer 25 functions as the other of the source electrode and the drain electrode.

A conductive layer 14 is provided over the substrate 11. The conductive layer 14 is electrically connected to the conductive layer 24 and functions as a wiring. The conductive layer 14 is preferably embedded in an insulating layer 31 functioning as an interlayer insulating layer as illustrated in FIG. 1B and the like. In that case, the top surface of the conductive layer 14 is preferably substantially level with the top surface of the insulating layer 31.

Note that in this specification and the like, the expression “substantially level with each other” indicates components having substantially the same level from a reference surface (e.g., a flat surface such as a substrate surface) in a cross-sectional view. For example, surfaces processed by planarization treatment (typically, CMP (chemical mechanical polishing) treatment) are substantially level with each other. Although surfaces processed by planarization treatment may not strictly be level with each other depending on materials of films or the like; however, such a case is also referred to as “substantially level with” in this specification and the like.

The conductive layer 24 is provided to be in contact with the top surface of the conductive layer 14. As illustrated in FIG. 1B and the like, the conductive layer 24 may be embedded in an insulating layer 32 functioning as an interlayer insulating layer.

An insulating layer 29a, an insulating layer 28, and an insulating layer 29b are provided to cover part of the conductive layer 24 and the insulating layer 32. Moreover, the conductive layer 25 is provided over the insulating layer 29b. An opening 20 reaching the conductive layer 24 is provided in the conductive layer 25, the insulating layer 29b, the insulating layer 28, and the insulating layer 29a. In other words, side walls (side surfaces) of the conductive layer 25, the insulating layer 29b, the insulating layer 28, and the insulating layer 29a along the opening 20 overlap with the conductive layer 24.

The semiconductor layer 21 is in contact with the top surface of the conductive layer 24 positioned at the bottom of the opening 20; a side surface of the insulating layer 29a, a side surface of the insulating layer 28, a side surface of the insulating layer 29b and a side surface of the conductive layer 25 along the opening 20; and the top surface of the conductive layer 25. A portion of the semiconductor layer 21 that is in contact with the conductive layer 25 functions as one of a source region and a drain region, a portion of the semiconductor layer 21 that is in contact with the conductive layer 24 functions as the other of the source region and the drain region, and a region of the semiconductor layer 21 between the above portions (in particular, a region in contact with the insulating layer 28) functions as a region where a channel is formed (a channel formation region). It is preferable that in the semiconductor layer 21, a region in contact with the insulating layer 29a and a region in contact with the insulating layer 29b have a higher carrier concentration and a lower resistance than the channel formation region.

The insulating layer 22 functioning as the gate insulating layer is provided to cover the insulating layer 29b, the conductive layer 25, and the semiconductor layer 21. In addition, the conductive layer 23 functioning as the gate electrode is provided to cover the insulating layer 22.

As described above, the semiconductor layer 21 includes a portion that is in contact with the side surface of the insulating layer 28 and functions as a channel formation region. The insulating layer 22 includes a portion facing the side surface of the insulating layer 28 with the semiconductor layer 21 therebetween. The conductive layer 23 includes a portion facing the side surface of the insulating layer 28 with the semiconductor layer 21 and the insulating layer 22 therebetween. An interface between the semiconductor layer 21 and the insulating layer 22 and an interface between the insulating layer 22 and the conductive layer 23 each include a portion parallel to the side surface of the insulating layer 28.

An insulating layer 33 and an insulating layer 39 are stacked to cover the insulating layer 22 and the conductive layer 23. An insulating layer 34 functioning as an interlayer insulating layer and a conductive layer 13 embedded in the insulating layer 34 are provided over the insulating layer 39. An opening is provided in the insulating layer 39 and the insulating layer 33 in a position overlapping with the conductive layer 24. Furthermore, the conductive layer 23 is provided to cover the opening 20, and thus has a top surface forming a depressed portion (a concave portion). The conductive layer 13 is provided to fill the opening of the insulating layer 39, the opening of the insulating layer 33, and the depressed portion defined by the conductive layer 23. Accordingly, the area where the conductive layer 23 is in contact with the conductive layer 13 is increased, and not only a reduction in the contact resistance therebetween but also an increase in the mechanical strength can be achieved.

The conductive layer 13 is electrically connected to the conductive layer 23 and functions as a wiring. Since the conductive layer 23 is provided in the opening 20, the thickness of the conductive layer 23 needs to be sufficiently smaller than the diameter of the opening 20 (e.g., less than or equal to one-fifth, or less than or equal to one-tenth); thus, the electric resistance cannot be sufficiently reduced in some cases. Thus, the conductive layer 13 that is thicker than the conductive layer 23 and has low electric resistance is preferably provided to be in contact with the conductive layer 23.

The conductive layer 13 is positioned over the insulating layer 39, and a portion embedded in the insulating layer 34 functions as a wiring. The top surface of the conductive layer 13 and the top surface of the insulating layer 34 are subjected to planarization treatment, and the top surfaces are substantially level with each other.

The semiconductor layer 21 preferably includes a metal oxide (an oxide semiconductor).

Examples of the metal oxide that can be used for the semiconductor layer 21 include indium oxide, gallium oxide, and zinc oxide. The metal oxide preferably contains at least In or Zn. The metal oxide preferably contains two or three selected from In, an element M, and Zn. The element M is a metal element or a metalloid element that has a high bonding energy with oxygen, such as a metal element or a metalloid element whose bonding energy with oxygen is higher than that of indium. Specific examples of the element M include Al, Ga, Sn, Y, Ti, V, Cr, Mn, Fe, Co, Ni, Zr, Zo, Hf, Ta, W, La, Ce, Nd, Mg, Ca, Sr, Ba, B, Si, Ge, and Sb. The element M included in the metal oxide is preferably one or more kinds of the above elements, and specifically, the element M is preferably one or more kinds selected from Al, Ga, Y, and Sn, and is further preferably Ga. Hereinafter, a metal oxide containing indium, M, and zinc is referred to as In-M-Zn oxide in some cases. In this specification and the like, a metal element and a metalloid element may be collectively referred to as a “metal element”, and a “metal element” in this specification and the like may refer to a metalloid element.

When a metal oxide is an In-M-Zn oxide, the atomic ratio of In is preferably higher than or equal to the atomic ratio of M in the In-M-Zn oxide. Examples of the atomic ratio of the metal elements of such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 or a composition in the neighborhood thereof. Note that a composition in the neighborhood includes the range of ±30% of an intended atomic ratio. By increasing the atomic ratio of indium in the metal oxide, the on-state current, field-effect mobility, or the like of the transistor can be increased.

The atomic ratio of In may be less than the atomic ratio of Min the In-M-Zn oxide. Examples of the atomic ratio of the metal elements in such an In-M-Zn oxide include In:M:Zn=1:3:2, In:M:Zn=1:3:3, In:M:Zn=1:3:4 or a composition in the neighborhood thereof. By increasing the atomic ratio of the element M in the metal oxide, generation of oxygen vacancies can be inhibited.

For the semiconductor layer 21, for example, In—Zn oxide, In—Ga oxide, In—Sn oxide, In—Ti oxide, In—Ga—Al oxide, In—Ga—Sn oxide, In—Ga—Zn oxide, In—Sn—Zn oxide, In—Al—Zn oxide, In—Ti—Zn oxide, In—Ga—Sn—Zn oxide, or In—Ga—Al—Zn oxide can be used. Alternatively, Ga—Zn oxide may be used.

Note that the metal oxide may contain, instead of indium or in addition to indium, one or more kinds of metal elements with larger period numbers. As the overlap between orbits of metal elements is larger, the carrier conductivity in the metal oxide tends to be higher. Thus, when the transistor includes metal elements with larger period numbers, the field-effect mobility of the transistor can be increased in some cases. Examples of the metal elements with larger period numbers include metal elements belonging to Period 5 and metal elements belonging to Period 6. Specific examples of the metal elements include Y, Zr, Ag, Cd, Sn, Sb, Ba, Pb, Bi, La, Ce, Pr, Nd, Pm, Sm, and Eu. Note that La, Ce, Pr, Nd, Pm, Sm, and Eu are referred to as light rare earth elements.

The metal oxide may contain one or more kinds of nonmetallic elements. When the metal oxide contains the nonmetallic elements, the field-effect mobility of the transistor can be increased in some cases. Examples of the nonmetallic element include carbon, nitrogen, phosphorus, sulfur, selenium, fluorine, chlorine, bromine, and hydrogen.

A sputtering method or an atomic layer deposition (ALD) method can be suitably used for forming the metal oxide. Note that in the case where the metal oxide is formed by a sputtering method, the composition of the deposited metal oxide may be different from the composition of a target. In particular, the content of the zinc in the deposited metal oxide may be reduced to approximately 50% of that of the target.

In this specification and the like, the content of a certain metal element in the metal oxide refers to the ratio of the number of atoms of the element to the total number of atoms of metal elements contained in the metal oxide. In the case where a metal oxide contains a metal element X, a metal element Y, and a metal element Z whose atomic numbers are respectively represented by A_{X}, A_{Y}, and A_{Z}, the content of the metal element X can be represented by A_{X}/(A_{X}+A_{Y}+A_{Z}). Moreover, in the case where the atomic ratio of the metal element X to the metal element Y and the metal element Z contained in the metal oxide is represented by B_{X}:B_{Y}:B_{Z}, the content ratio of the metal element X can be represented by B_{X}/(B_{X}+B_{Y}+B_{Z}).

For example, in the case of the metal oxide containing In, higher content of In enables the transistor to have high on-state current.

With use of a metal oxide that does not contain Ga or has low Ga content in the semiconductor layer 21, the transistor can be highly reliable against positive bias application. That is, the amount of change in the threshold voltage of the transistor in the PBTS (positive bias temperature stress) test can be small. Meanwhile, with use of a metal oxide that contains Ga, the Ga content is preferably lower than the In content. Thus, the transistor with high mobility and high reliability can be achieved.

Meanwhile, the high content of Ga enables the transistor to be highly reliable against light. That is, the amount of change in the threshold voltage of the transistor in the NBTIS (negative bias temperature illumination stress) test can be small. Specifically, in a metal oxide in which the atomic ratio of Ga is higher than or equal to that of In, the band gap is increased and accordingly the amount of change in the threshold voltage of the transistor in the NBTIS test can be reduced.

Furthermore, a metal oxide having a high zinc content has high crystallinity whereby diffusion of impurities can be inhibited. Consequently, a change in the electrical characteristics of the transistor can be inhibited and the reliability can be increased.

The semiconductor layer 21 may have a stacked-layer structure of two or more metal oxide layers. The two or more metal oxide layers included in the semiconductor layer 21 may have the same composition or substantially the same compositions. With the stacked-layer structure of metal oxide layers having the same composition, the manufacturing cost can be reduced because the metal oxide layers can be formed with the same sputtering target. Note that a stacked-layer structure including two or more oxide semiconductor layers having different compositions may be employed.

It is preferable to use a metal oxide layer having crystallinity as the semiconductor layer 21. For example, a metal oxide layer having a CAAC (c-axis aligned crystal) structure, a polycrystalline structure, a nano-crystal (nc) structure, or the like can be used. With the use of the metal oxide layer having crystallinity as the semiconductor layer 21, the density of defect states in the semiconductor layer 21 can be reduced, which enables the semiconductor device to have high reliability.

The higher the crystallinity of the metal oxide layer used as the semiconductor layer 21 is, the lower the density of defect states in the semiconductor layer 21 can be. By contrast, the use of a metal oxide layer with low crystallinity enables a transistor through which a large amount of current flows.

A transistor using an oxide semiconductor (hereinafter also referred to as an OS transistor) has much higher field-effect mobility than a transistor using amorphous silicon. In addition, an OS transistor has an extremely low leakage current flowing between a source and a drain in an off state (hereinafter also referred to as off-state current), and charge accumulated in a capacitor that is connected in series to the transistor can be retained for a long period. Furthermore, the power consumption of the semiconductor device can be reduced with the OS transistor.

The semiconductor device that is one embodiment of the present invention can be used for a display device, for example. To increase the emission luminance of the light-emitting device included in a pixel circuit of a display device, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a transistor including silicon (hereinafter referred to as a Si transistor), a high voltage can be applied between the source and the drain of the OS transistor. Thus, by using an OS transistor as a driving transistor included in the pixel circuit, the amount of current flowing through the light-emitting device can be increased, resulting in an increase in emission luminance of the light-emitting device.

When transistors operate in a saturation region, a change in source-drain current with respect to a change in gate-source voltage can be smaller in an OS transistor than in a Si transistor. Accordingly, when an OS transistor is used as the driving transistor included in the pixel circuit, the amount of current flowing through the light-emitting device can be precisely controlled. Accordingly, the number of gray levels in the pixel circuit can be increased. Moreover, current can be made flow stably even when the electrical characteristics (e.g., resistance) in the light-emitting device change or the electrical characteristics in the light-emitting device vary.

As described above, by using an OS transistor as the driving transistor included in the pixel circuit, it is possible to achieve “inhibition of black floating”, “increase in emission luminance”, “increase in the number of gray levels”, “inhibition of the effect due to the variation in light-emitting devices”, and the like.

A change in electrical characteristics of an OS transistor due to irradiation with radiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a neutron beam, a proton beam, and a neutron beam).

Note that the semiconductor material that can be used for the semiconductor layer 21 is not limited to the oxide semiconductor. For example, a single-element semiconductor or a compound semiconductor can be used. Examples of the single-element semiconductor include silicon (such as single crystal silicon, polycrystalline silicon, microcrystalline silicon, and amorphous silicon) and germanium. Examples of the compound semiconductor include gallium arsenide and silicon germanium. Examples of the compound semiconductor include an organic semiconductor, a nitride semiconductor, and an oxide semiconductor. These semiconductor materials may contain an impurity as a dopant.

Alternatively, the semiconductor layer 21 may contain a layered substance that functions as a semiconductor. The layered substance is a general term of a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substances include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

There is no particular limitation on the crystallinity of a semiconductor material used for the semiconductor layer 21, and any of an amorphous semiconductor, a single crystal semiconductor, and a semiconductor having crystallinity other than single crystal (a polycrystalline semiconductor, a microcrystalline semiconductor, or a semiconductor partly including crystal regions) may be used. A semiconductor having crystallinity is preferably used because degradation of the transistor characteristics can be inhibited.

Each of the top surfaces of the conductive layer 24 and the conductive layer 25 is in contact with the semiconductor layer 21. Here, in the case where the semiconductor layer 21 is formed using an oxide semiconductor, when the conductive layer 24 or the conductive layer 25 is formed using, for example, a metal that is likely to be oxidized such as aluminum, an insulating oxide (e.g., aluminum oxide) is formed between the conductive layer 24 or the conductive layer 25 and the semiconductor layer 21, which might prevent electrical continuity between the conductive layer 24 or a conductive layer 25 and the semiconductor layer 21. Therefore, a conductive material that is less likely to be oxidized, a conductive material that maintains low electric resistance even after being oxidized, or an oxide conductive material is preferably used for the conductive layer 24 and the conductive layer 25.

For example, it is preferable to use tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like as the conductive layer 24 and the conductive layer 25. These materials are preferable because they are conductive materials that are less likely to be oxidized or a material that maintains the conductivity even after being oxidized.

Alternatively, a conductive oxide such as indium oxide, zinc oxide, In—Sn oxide, In—Zn oxide, In—W oxide, In—W—Zn oxide, In—Ti oxide, In—Ti—Sn oxide, In—Sn oxide containing silicon, or zinc oxide to which gallium is added can be used. A conductive oxide containing indium is particularly preferable because of its high conductivity.

The insulating layer 22 functions as a gate insulating layer. In the case where the semiconductor layer 21 is formed using an oxide semiconductor, an oxide insulating film is preferably used as at least a film of the insulating layer 22 that is in contact with the semiconductor layer 21. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, as the insulating layer 22, a nitride insulating film of silicon nitride, silicon nitride oxide, aluminum nitride, or aluminum nitride oxide can also be used. The insulating layer 22 may also have a stacked-layer structure, e.g., a stacked-layer structure including at least one oxide insulating film and at least one nitride insulating film.

Note that in this specification and the like, an oxynitride refers to a material that contains more oxygen than nitrogen. A nitride oxide refers to a material that contains more nitrogen than oxygen.

The conductive layer 23 functions as a gate electrode and a variety of conductive materials can be used. The conductive layer 23 can be formed using, for example, one or more of chromium, copper, aluminum, gold, silver, zinc, molybdenum, tantalum, titanium, tungsten, manganese, nickel, iron, cobalt, molybdenum, and niobium; or an alloy including one or more of the above-described metals as its components. For the conductive layer 23, the nitride and the oxide that can be used for the conductive layer 24 and the conductive layer 25 may be used.

The insulating layer 28 includes a portion in contact with the semiconductor layer 21. In the case where the semiconductor layer 21 is formed using an oxide semiconductor, an oxide is preferably used for at least a portion of the insulating layer 28 that is in contact with the semiconductor layer 21 in order to improve the properties of the interface between the semiconductor layer 21 and the insulating layer 28. For example, silicon oxide or silicon oxynitride can be suitably used.

Moreover, a film from which oxygen is released by heating is preferably used for the insulating layer 28. Accordingly, oxygen can be supplied to the semiconductor layer 21 owing to heat applied during the manufacturing process of the transistor 10; thus, the amount of oxygen vacancy in the semiconductor layer 21 can be reduced, and reliability can be improved. Examples of a method for supplying oxygen to the insulating layer 28 include heat treatment in an oxygen atmosphere and plasma treatment in an oxygen atmosphere. Alternatively, an oxide film may be deposited by a sputtering method in an oxygen atmosphere to supply oxygen to the top surface of the insulating layer 28. After that, the metal oxide film may be removed.

The insulating layer 28 is preferably formed by a deposition method such as a sputtering method or a plasma CVD method. In particular, a film is formed by a sputtering method as a deposition method that does not use a hydrogen gas for a deposition gas, a film having an extremely low hydrogen content can be formed. Consequently, supply of hydrogen to the semiconductor layer 21 is inhibited and the electrical characteristics of the transistor 10 can be stabilized.

As the insulating layer 29a and the insulating layer 29b, films in which oxygen is less likely to be diffused are preferably used. Accordingly, it is possible to prevent oxygen contained in the insulating layer 28 from being transmitted toward the side of the insulating layer 32 through the insulating layer 29a and being transmitted toward the side of the insulating layer 33 through the insulating layer 29b due to heating. In other words, when the upper and lower sides of the insulating layer 28 are sandwiched between the insulating layer 29a and the insulating layer 29b in which oxygen is less likely to be diffused, oxygen contained in the insulating layer 28 can be enclosed. Thus, oxygen can be effectively supplied to the semiconductor layer 21.

As the insulating layer 29a and the insulating layer 29b, for example, one or more of silicon nitride, silicon nitride oxide, silicon oxynitride, aluminum oxide, aluminum oxynitride, aluminum nitride, hafnium oxide, and hafnium aluminate can be used. Silicon nitride and silicon nitride oxide can be particularly suitably used for the insulating layer 29a and the insulating layer 29b because the silicon nitride and the silicon nitride oxide release fewer impurities (e.g., water and hydrogen) and are less likely to transmit oxygen and hydrogen.

The conductive layer 13 and the conductive layer 14 function as wirings and thus preferably have low electrical resistance. The conductive layer 13 and the conductive layer 14 preferably contain a metal or an alloy. Furthermore, the thickness of the conductive layer 13 is preferably larger than that of the conductive layer 23, and the thickness of the conductive layer 14 is preferably larger than that of the conductive layer 24.

For the conductive layer 13 and the conductive layer 14, a conductive material that can be used for the conductive layer 23 can be used.

The insulating layer 33, the insulating layer 34, and the insulating layer 39 each function as an interlayer insulating film. The insulating layer 39 preferably functions as an etching stopper in processing the insulating layer 34. Thus, for the insulating layer 39, a material different from those for the insulating layer 33 and the insulating layer 34 is preferably used. For example, silicon oxide can be used for the insulating layer 33 and the insulating layer 34, and silicon nitride can be used for the insulating layer 39. Note that without limitation to this, for the insulating layer 33 and the insulating layer 34, the above-described materials that can be used for the insulating layer 28 can be used, and for the insulating layer 39, any of the above-described materials that can be used for the insulating layer 29a and the insulating layer 29b can be used.

Here, as in the insulating layer 28, an oxide that releases oxygen by heating is preferably used for the insulating layer 33. Accordingly, oxygen released from the insulating layer 33 is supplied to the semiconductor layer 21 through the insulating layer 22. In that case, for the insulating layer 39, like the insulating layer 29a and the insulating layer 29b, an insulating material that is less likely to transmit oxygen, is preferably used. Furthermore, for a portion of the conductive layer 13 that is in contact with the insulating layer 33, a conductive material that is less likely to be oxidized or a material that maintains the conductivity even after being oxidized, as in the conductive layer 24 or the like, is preferably used. For example, the conductive layer 13 is preferably a stacked-layer film of a film containing a conductive material that is less likely to be oxidized or a material that maintains the conductivity even after being oxidized and a film containing a low-resistance conductive material. For the conductive material that is less likely to be oxidized or the material that maintains the conductivity even after being oxidized, the description of the conductive layer 24 and the conductive layer 25 can be referred to.

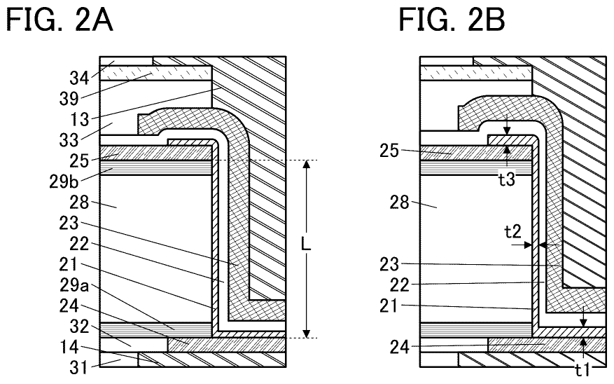

FIG. 2A is an enlarged view of a cross section.

In this specification and the like, the channel length L of the transistor 10 refers to the shortest distance between a portion of the semiconductor layer 21 in contact with the conductive layer 24 and a portion of the semiconductor layer 21 in contact with the conductive layer 25 as illustrated in FIG. 2A. In the case where the side surfaces of the openings in the insulating layer 29a, the insulating layer 28, and the insulating layer 29b are perpendicular to the substrate surface, the channel length L is the shortest and corresponds to the sum of the thicknesses of the insulating layer 29a, the insulating layer 28, and the insulating layer 29b.

The semiconductor layer 21 is formed along the side surfaces of the insulating layer 29a, the insulating layer 28, and the insulating layer 29b in the opening. At this time, as for a film deposited by a deposition method such as a sputtering method or a plasma CVD method, the thickness of a film formed on a surface inclined to or perpendicular to the substrate surface tends to be smaller than the thickness of a film formed on a surface horizontal to the substrate surface. Thus, in the case where the semiconductor layer 21 is formed by a sputtering method, as illustrated in FIG. 2B, when the thickness of a portion of the semiconductor layer 21 in contact with the top surface of the conductive layer 24 is t1, the thickness of a portion of the semiconductor layer 21 in contact with the insulating layer 28 is t2, and the thickness of a portion of the semiconductor layer 21 in contact with the top surface of the conductive layer 25 is t3, t2 is thinner than t1 and t2 is thinner than t3. Note that a portion of the semiconductor layer 21 in contact with each of the side surfaces of the conductive layer 25, the insulating layer 29a, and the insulating layer 29b can be formed to be thinner than t1 and t3 in a similar manner.

In a similar manner, the thicknesses of a portion of the insulating layer 22 and a portion of the conductive layer 23 that are formed along the side surface of the insulating layer 28 and the like in the opening can be smaller than those of a portion of the insulating layer 22 and a portion of the conductive layer 23 that are formed over the top surfaces of the conductive layer 24 and the conductive layer 25.

Meanwhile, in the case where a film is formed by an ALD method or the like, the film with a uniform thickness can be deposited regardless of the tilt angle of a formation surface, so that the difference in thickness as illustrated in FIG. 2B hardly occurs in the semiconductor layer 21, the insulating layer 22, the conductive layer 23, and the like in some cases.

The shapes of the side surfaces of the insulating layer 28, the insulating layer 29a, and the insulating layer 29b in the opening 20 are not limited to the above, and can be a variety of shapes depending on a processing method.

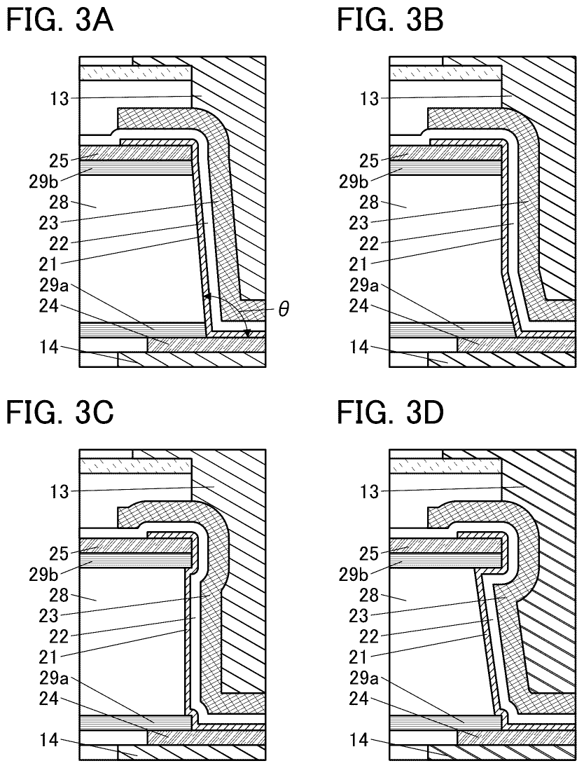

FIG. 3A is an example of the case where in the opening 20, the side surfaces of the insulating layer 28, the insulating layer 29a, and the insulating layer 29b are inclined upward, i.e., the side surfaces are so-called tapered shapes. Here, when an angle between the side surface of the insulating layer 28 in the opening 20 and the top surface of the insulating layer 24 positioned at the bottom of the opening 20 is denoted by an angle θ, it is preferable that the angle θ include a portion greater than or equal to 90° and less than or equal to 135°, preferably less than or equal to 125°, further preferably less than or equal to 120°, still further preferably less than or equal to 110°. As the angle θ is closer to a right angle, i.e., the side surface of the insulating layer 28 is closer to vertical, the area occupied by the transistor 10 can be reduced. Note that in the case where a stack of the semiconductor layer 21, the insulating layer 22, and the conductive layer 23 can cover the side surface of the insulating layer 28, the angle θ may be less than 90°.

FIG. 3B is an example of the case where the insulating layer 28 includes a portion of the side surface with different inclination angles. For example, when the etching conditions are changed in the middle of the etching for forming the opening 20 in the insulating layer 28, the opening 20 can have a shape as illustrated in FIG. 3B. For example, in the case of using dry etching processing, by changing electric power, bias power, pressure, kinds of gas, flow rate of a gas, or the like in the middle, the opening 20 including a portion with different inclination angles can be formed.

FIG. 3C and FIG. 3D each illustrate an example of the case where the side surface of the insulating layer 28 is positioned on the inner side of the side surfaces of the insulating layer 29a and the insulating layer 29b. In other words, the side surfaces of the insulating layer 29a and the insulating layer 29b protrude beyond the side surface of the insulating layer 28. FIG. 3C illustrates the case where the side surface of the insulating layer 28 is substantially perpendicular to the top surface of the conductive layer 24, and FIG. 3D is an example of the case where the side surface of the insulating layer 28 is inclined upward. In the case where the opening 20 has such a shape, the semiconductor layer 21, the insulating layer 22, and the conductive layer 23 are preferably deposited by a deposition method with high step coverage, such as an ALD method.

The side surfaces of the insulating layer 28, the insulating layer 29a, and the insulating layer 29b may include a wave shape or an uneven shape. The larger the surface areas of the side surfaces of the insulating layer 28, the insulating layer 29a, and the insulating layer 29b are, the longer the channel length L of the transistor can be. In this manner, the channel length L of the transistor can be controlled by the shapes of the side surfaces of the insulating layer 28, the insulating layer 29a, and the insulating layer 29b.

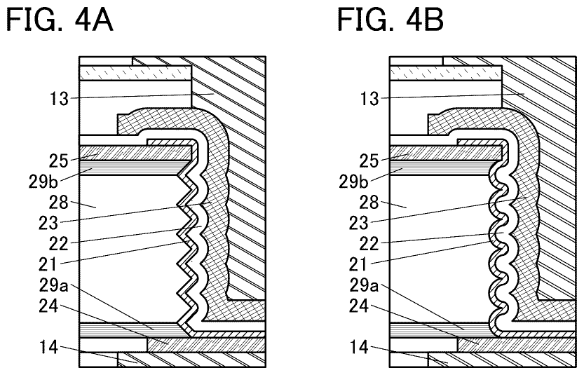

FIG. 4A and FIG. 4B each illustrate an example in which projections and depressions are formed on the side surfaces of the insulating layer 28, the insulating layer 29a, and the insulating layer 29b. FIG. 4A is an example of the case where a cross section has a zigzag shape, and FIG. 4B is an example of the case where a cross section has a wave shape. For example, in etching the insulating layer 28, the insulating layer 29a, and the insulating layer 29b, by performing an etching step and a polymer deposition step repeatedly, regular projections and depressions can be formed on the side surfaces of the insulating layer 28, the insulating layer 29a, and the insulating layer 29b. Even in the case where the opening 20 has such a shape, the semiconductor layer 21, the insulating layer 22, and the conductive layer 23 are preferably deposited by a deposition method providing high step coverage, such as an ALD method.

### Structure Example 2

A structure example whose structure is partly different from that of Structure example 1 is described below. Note that description of the same portions as those in Structure example 1 is omitted below in some cases.

### Structure Example 2-1

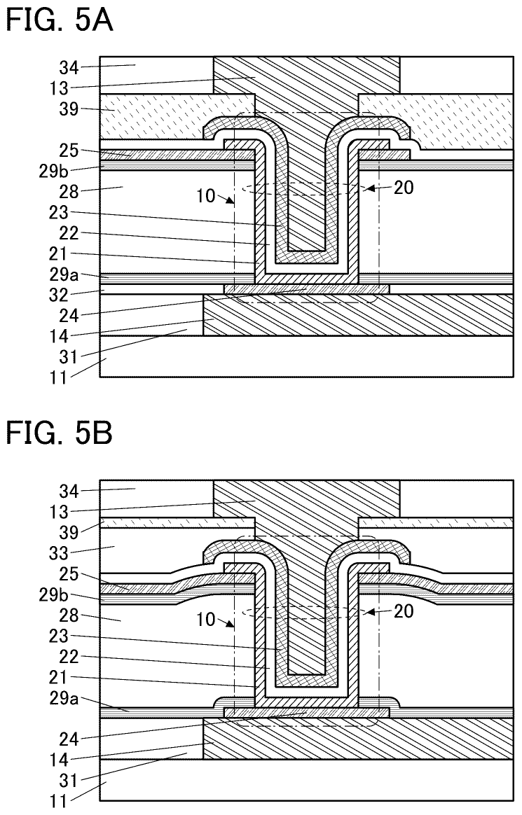

FIG. 5A is an example of the case where the insulating layer 33 in FIG. 1B is not provided. The insulating layer 39 is provided to cover the top surfaces of the insulating layer 22 and the conductive layer 23. With such a structure, the manufacturing process of the transistor 10 can be simplified.

### Structure Example 2-2

FIG. 5B is an example of the case where the insulating layer 32 in FIG. 1B is not provided. The conductive layer 24 is provided over the conductive layer 14, and the insulating layer 29a is provided to cover the end portions of the conductive layer 24. The insulating layer 28, the insulating layer 29b, the conductive layer 25, and the insulating layer 22 each include an uneven shape on the top surface reflecting a step shape thereunder.

### Structure Example 2-3

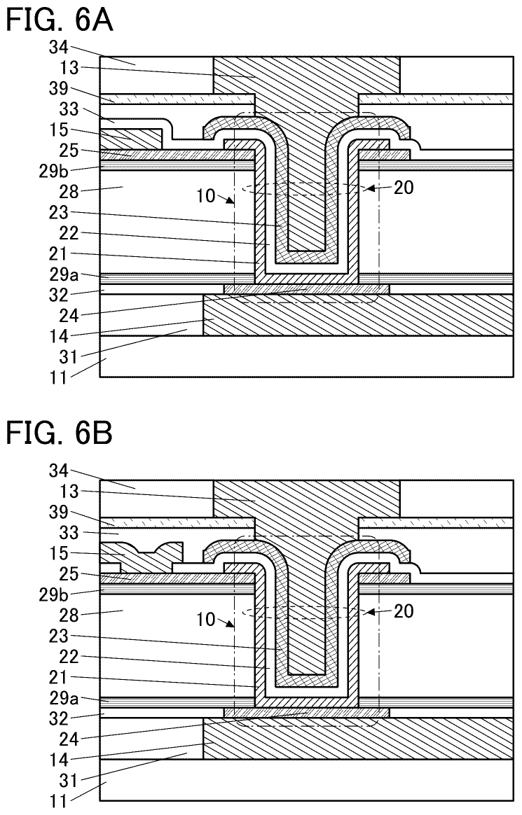

FIG. 6A is an example of the case where a conductive layer 15 in contact with the conductive layer 25 is provided. The conductive layer 15 functions as a wiring. A conductive material that can be used for the conductive layer 14 can be used for the conductive layer 15.

As described in Structure example 1, in the case where the semiconductor layer 21 is formed using an oxide semiconductor, a conductive oxide or the like is preferably used for the conductive layer 25 in contact with the bottom surface of the semiconductor layer 21; but does not have a sufficient conductivity for a wiring in some cases. Thus, the conductive layer 15 having a conductivity higher than that of the conductive layer 25 is preferably provided over and in contact with the conductive layer 25.

As illustrated in FIG. 6B, the conductive layer 15 may be provided over the insulating layer 22. In this case, the conductive layer 15 and the conductive layer 25 are electrically connected to each other in an opening portion provided in the insulating layer 22. Both of the formation of the opening portion in the insulating layer 22 and the formation of the conductive layer 15 can be performed after the formation of the conductive layer 23 of the transistor 10; thus, the formation of the insulating layer 22 functioning as the gate insulating layer and the formation of the conductive layer 23 functioning as the gate electrode can be performed successively, whereby a highly reliable transistor can be achieved.

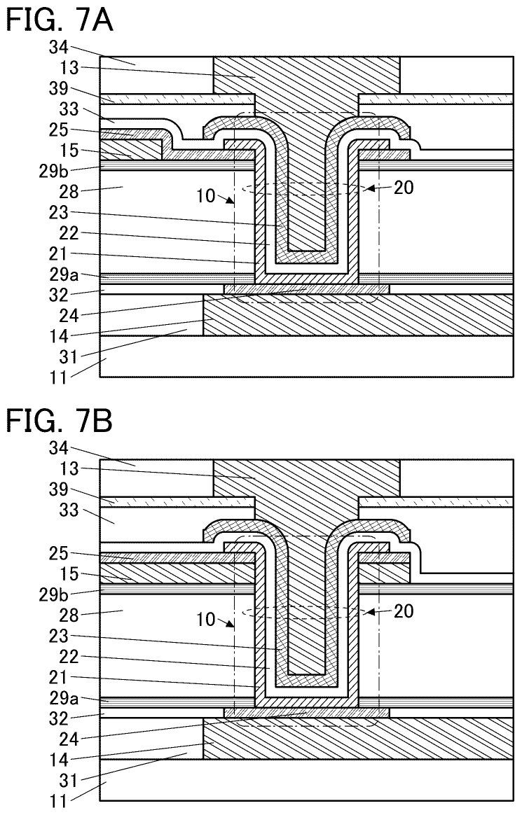

As illustrated in FIG. 7A, a structure in which the bottom surface of the conductive layer 25 and the conductive layer 15 are in contact with each other may be employed. At this time, as illustrated in FIG. 7B, the conductive layer 25 and the conductive layer 15 may be processed using the same photomask. In that case, the conductive layer 25 and the conductive layer 15 are stacked and their end portions can be substantially aligned with each other. In the structure illustrated in FIG. 7B, an oxide film may be formed at the interface between the semiconductor layer 21 and the conductive layer 15.

### Structure Example 2-4

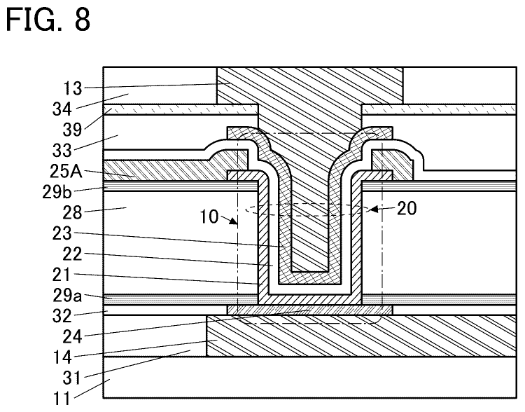

FIG. 8 illustrates an example of the case where the conductive layer 25 in FIG. 1B is replaced by a conductive layer 25A. The conductive layer 25A is provided to be in contact with the top surface of the semiconductor layer 21. With such a structure, even in the case where an oxide semiconductor is used for the semiconductor layer 21, a low-resistance metal film or alloy film can be used for the conductive layer 25A. For example, a conductive material that can be used for the conductive layer 14 can be used for the conductive layer 25A.

### Structure Example 3

Shapes of the opening 20 in which the transistor 10 is provided and examples in which a plurality of transistors are connected will be described below.

### [Shape of the Opening]

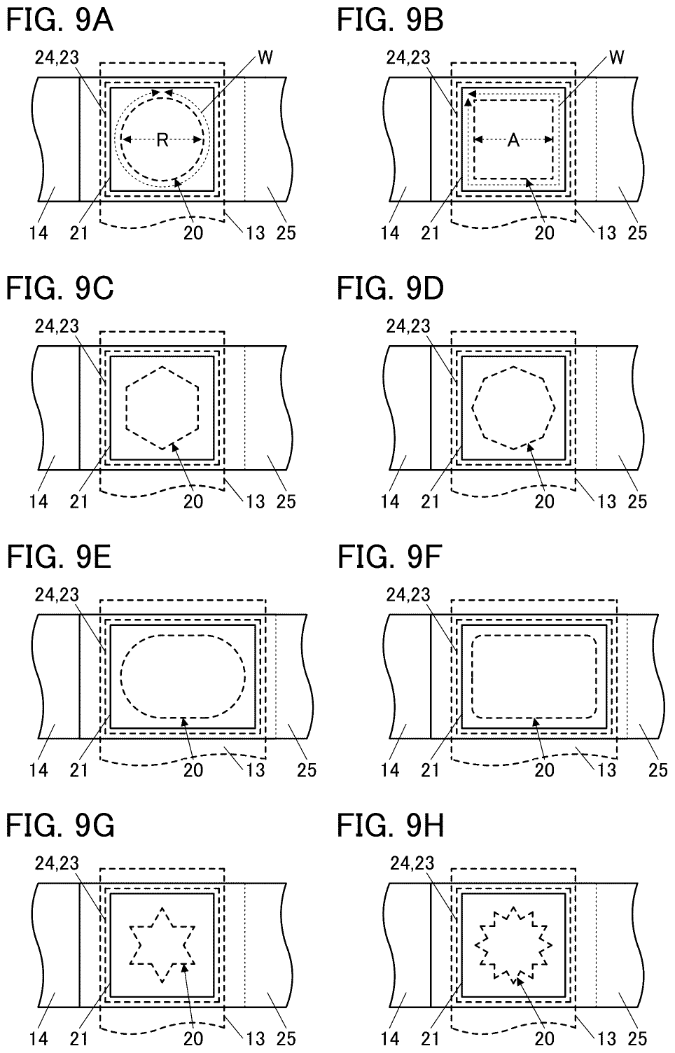

FIG. 9A illustrates a schematic top view of the opening 20 and its surroundings. In FIG. 9A, the conductive layer 14, the conductive layer 25, and the semiconductor layer 21 are illustrated by solid lines, and the outlines of the opening 20, the conductive layer 23, the conductive layer 24, and the conductive layer 13 are illustrated by dashed lines.

Note that although the description is made here assuming that the diameter of the opening 20 does not change in the depth direction, in the case where the diameter of the opening 20 changes in the depth direction as illustrated in FIG. 3A and the like, the average value of the diameter at the highest position, the diameter at the lowest position, and the diameter at the intermediate position of the insulating layer 28 in a cross-sectional view can be the diameter of the opening 20. Note that without limitation to this, any of the diameter at the highest position, the diameter at the lowest position, the diameter at the intermediate position of the insulating layer 28 may be the diameter of the opening 20.

In FIG. 9A, the conductive layer 23 and the conductive layer 24 are provided on the inner side of the outline of the conductive layer 13, the semiconductor layer 21 is provided on the inner side of the outline of the conductive layer 23 and the outline of the conductive layer 24, and the opening 20 is provided on the inner side of the outline of the semiconductor layer 21. In addition, the case where the conductive layer 23 and the conductive layer 24 have substantially the same top surface shape is illustrated. In addition, the width of the conductive layer 14 is substantially the same as the width of the conductive layer 25, and the conductive layer 23, the conductive layer 24, the semiconductor layer 21, and the opening 20 are provided on the inner side of the outline of the conductive layer 14. Note that the top surface shapes of each layer are not limited to the above. At least the opening 20 is positioned on the inner side of the outlines of the semiconductor layer 21, the conductive layer 23, and the conductive layer 24. For example, the semiconductor layer 21, the conductive layer 23, the conductive layer 24, or the like may include a portion positioned on the outer side of the conductive layer 14, the conductive layer 25, or the conductive layer 13. The outlines of the conductive layer 23 and the conductive layer 24 may be different.

FIG. 9A illustrates the case where the top surface shape of the opening 20 is a circular shape with a diameter R. At that time, the channel width W of the transistor 10 is equal to the length of the circumference of the opening 20. That is, the channel width W is π×R. In this manner, when the top surface shape of the opening 20 is a circular shape, the transistor with the smallest channel width W can be achieved.

FIG. 9B illustrates an example of the case where the top surface shape of the opening 20 is a square whose length of one side is A. In this case, the channel width W of the transistor 10 is 4×A.

FIG. 9C illustrates an example of the case where the top surface shape of the opening 20 is a regular hexagon. FIG. 9D illustrates an example of the case where the top surface shape of the opening 20 is a regular octagon. Note that shapes are not limited thereto and can be a variety of polygonal shapes.

Here, in a photolithography method, as a pattern to be processed becomes finer, the influence of light diffraction becomes more difficult to ignore; thus, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface shape of a light-emitting element has a polygonal shape with rounded corners, an elliptical shape, a circular shape, or the like in some cases. Therefore, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

FIG. 9E illustrates the case where the top surface shape of the opening 20 has a shape in which half circles and straight lines are combined. FIG. 9F illustrates an example of the case where the top surface of the opening 20 is a rectangular shape with four rounded corners.

The larger the perimeter of the opening 20 is, the larger the channel width W can be. For example, as illustrated in FIG. 9G and FIG. 9H, when the top surface shape of the opening is a polygon with at least one inner angle greater than 180°, which is so-called a concave polygon, the channel width W can be increased without increasing the area occupied by the opening. FIG. 9G illustrates the case where the top surface shape of the opening 20 is a star hexagram, and FIG. 9H illustrates an example where the top surface shape of the opening 20 is a dodecagram.

### [Method for Connecting Transistors]

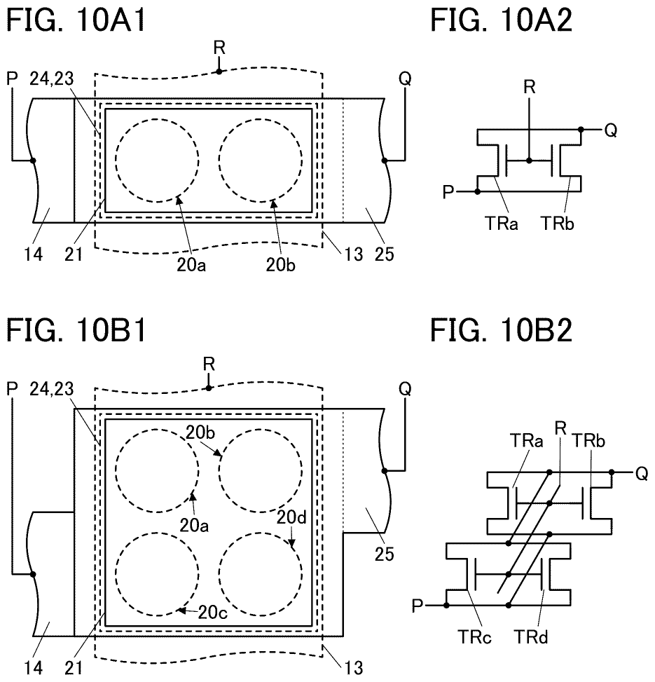

FIG. 10A1 is a schematic top view of a region including two transistors connected in parallel. Two openings (an opening 20a and an opening 20b) are provided between the conductive layer 14 and the conductive layer 13, and a transistor is formed in each of the opening 20a and the opening 20b.

Since the conductive layer 23, the conductive layer 24, and the conductive layer 25 are shared by the two transistors, the structure illustrated in FIG. 10A1 corresponds to the circuit illustrated in FIG. 10A2. Here, P is a wiring corresponding to the conductive layer 14, Q is a wiring corresponding to the conductive layer 25, and R is a wiring corresponding to the conductive layer 13, a transistor TRa is the transistor corresponding to the opening 20a, and a transistor TRb is the transistor corresponding to the opening 20b.

In the structure illustrated in FIG. 10A1 and FIG. 10A2, the two transistors are connected in parallel. In the case where the two transistors have equal channel lengths L and equal channel widths W, the structure illustrated in FIG. 10A1 and FIG. 10A2 can be regarded as one transistor having a channel length L and a channel width of 2×W.

FIG. 10B1 illustrates an example of a schematic top view in which four transistors are connected in parallel. In FIG. 10B1, four openings (openings 20a, 20b, 20c, and 20d) are provided. FIG. 10B2 is a circuit diagram corresponding to FIG. 101. The transistor TRa, the transistor TRb, a transistor TRc, and a transistor TRd are transistors corresponding to the opening 20a, the opening 20b, the opening 20c, and the opening 20d, respectively.

In the structure illustrated in FIG. 10B1 and FIG. 10B2, the four transistors are connected in parallel. When the four transistors have equal channel lengths L and equal channel widths W, the structure illustrated in FIG. 10B1 and FIG. 10B2 can be regarded as one transistor having a channel length L and a channel width of 4×W.

In this manner, a plurality of openings 20 are provided between the conductive layer 13 and the conductive layer 14 (or between the conductive layer 24 and the conductive layer 23), whereby a transistor whose channel width W is an integral multiple can be formed.

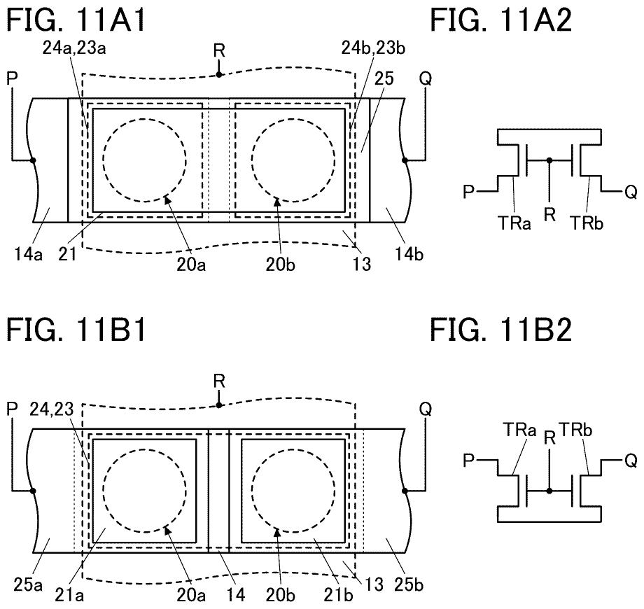

FIG. 11A1 is a schematic top view of the case where two transistors are connected in series. In FIG. 11A1, a pair of conductive layers 14 (a conductive layer 14a and a conductive layer 14b), a pair of conductive layers 23 (a conductive layer 23a and a conductive layer 23b), a pair of conductive layers 24 (a conductive layer 24a and a conductive layer 24b), and the like are included.

The conductive layer 24a, the opening 20a, the semiconductor layer 21, the conductive layer 23a, and the conductive layer 13 are provided over the conductive layer 14a. The conductive layer 24b, the opening 20b, the semiconductor layer 21, the conductive layer 23b, and the conductive layer 13 are provided over the conductive layer 14b.

The conductive layer 25 and the semiconductor layer 21 are shared by the two transistors, and the conductive layer 23a and the conductive layer 23b are electrically connected to each other by the conductive layer 13. FIG. 11A2 is a circuit diagram corresponding to FIG. 11A1. Note that P is a wiring corresponding to the conductive layer 14a, Q is a wiring corresponding to the conductive layer 14b, and R is a wiring corresponding to the conductive layer 13.

Although an example in which the conductive layer 23a and the conductive layer 23b are included is described here, one continuous conductive layer 23 which is shared by the two transistors may be employed. Also, although an example in which the semiconductor layer 21 is shared by the two transistors is described here, the semiconductor layer 21 may be provided separately.

The structure illustrated in FIG. 11B1 and FIG. 11B2 include a pair of conductive layers 25 (conductive layers 25a and 25b) and a pair of semiconductor layers 21 (semiconductor layers 21a and 21b).

Over the conductive layer 14, a region where the conductive layer 24, the opening 20a, the conductive layer 25a, the semiconductor layer 21a, the conductive layer 23, and the conductive layer 13 are stacked, and a region where the conductive layer 24, the opening 20b, the conductive layer 25b, the semiconductor layer 21b, the conductive layer 23, and the conductive layer 13 are stacked are included.

The conductive layer 14, the conductive layer 24, the conductive layer 23, and the conductive layer 13 are shared by the two transistors. FIG. 11B2 is a circuit diagram corresponding to FIG. 11B1. P is a wiring corresponding to the conductive layer 25a, Q is a wiring corresponding to the conductive layer 25b, and R is a wiring corresponding to the conductive layer 13.

Note that in FIG. 11B2, the conductive layer 23 and the conductive layer 24 may not be provided to be shared by the two transistors and may be provided separately for each transistor.

In this manner, when the gate and one of the source electrode and the drain electrode are shared, the two transistors can be connected in series. For example, in the case where each of the channel lengths L and the channel widths W of the two transistors are equal, the transistors can be regarded as a transistor having a channel length L×2 and a channel width W. In other words, when a plurality of transistors are positioned in series, a transistor whose L length is an integral multiple can be formed.

### Manufacturing Method Example

A manufacturing method example of the transistor of one embodiment of the present invention will be described below. Here, description will be made giving, as an example, the transistor 10 described in Structure example 1.

Note that thin films that constitute the semiconductor device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of a CVD method include a plasma-enhanced chemical vapor deposition (PECVD) method and a thermal CVD method. An example of a thermal CVD method is a metal organic chemical vapor deposition (MOCVD) method.

The thin films that constitute the semiconductor device (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

When the thin films that constitute the semiconductor device are processed, a photolithography method or the like can be used for the processing. Besides, a nanoimprinting method, a sandblasting method, a lift-off method, or the like may be used for the processing of the thin films. Alternatively, island-shaped thin films may be directly formed by a film formation method using a shielding mask such as a metal mask.

There are the following two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light used for light exposure in a photolithography method, it is possible to use light with the i-line (wavelength: 365 nm), light with the g-line (wavelength: 436 nm), light with the h-line (wavelength: 405 nm), or combined light of any of them. Alternatively, ultraviolet rays, KrF laser light, ArF laser light, or the like can be used. Light exposure may be performed by liquid immersion light exposure technique. As the light used for light exposure, extreme ultraviolet (EUV) light or X-rays may also be used. Instead of the light for light exposure, an electron beam can also be used. It is preferable to use extreme ultraviolet light, X-rays, or an electron beam because extremely minute processing can be performed. Note that a photomask is not needed when light exposure is performed by scanning with a beam such as an electron beam.

For etching of thin films, a dry etching method, a wet etching method, a sandblast method, or the like can be used.

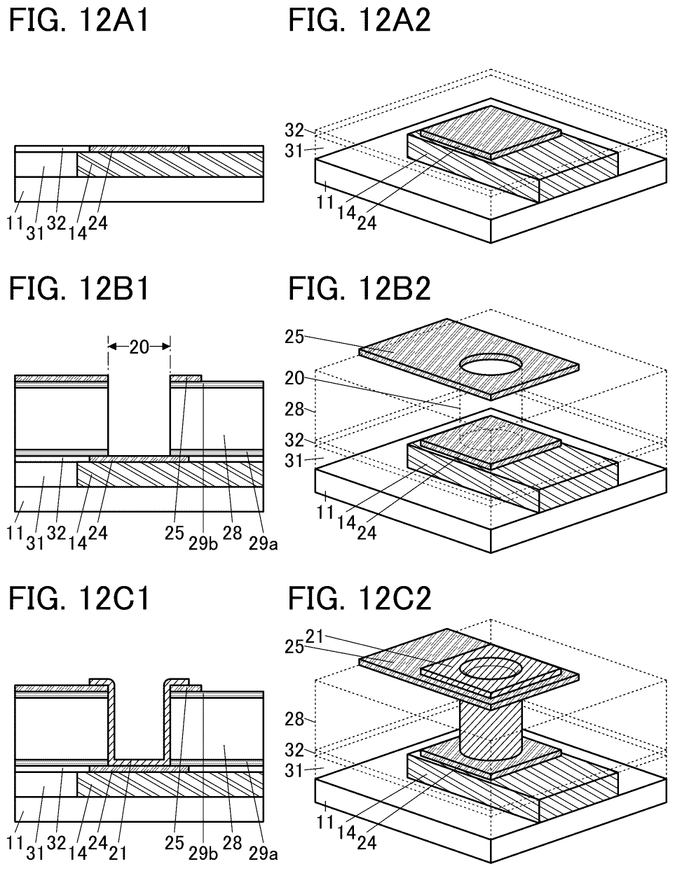

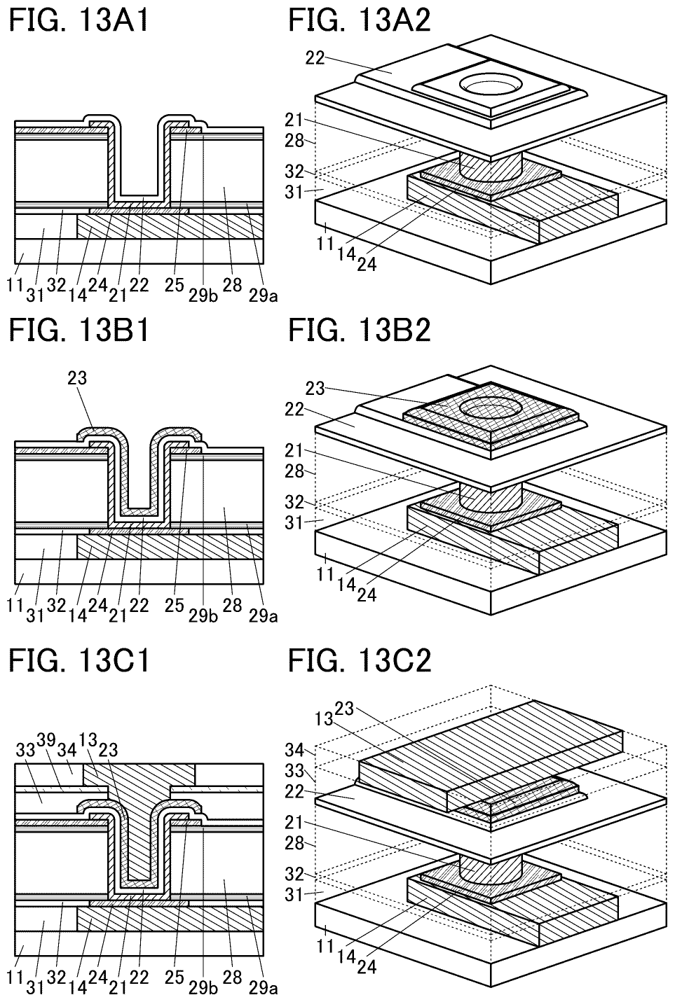

FIG. 12A1 to FIG. 13C1 are schematic cross-sectional views of steps in the manufacturing process of the transistor 10 described below. FIG. 12A2 to FIG. 13C2 are perspective views of steps. Note that in FIG. 12A2 to FIG. 13C2, some components are omitted and only outlines are denoted by dashed lines for easy understanding.

### [Preparation for Substrate 11]

First, the substrate 11 is prepared.

As the substrate, a substrate having at least heat resistance high enough to withstand heat treatment performed later can be used. In the case where an insulating substrate is used as the substrate, a glass substrate, a quartz substrate, a sapphire substrate, a ceramics substrate, an organic resin substrate, or the like can be used. Alternatively, a single crystal semiconductor substrate or a polycrystalline semiconductor substrate using silicon, silicon carbide, or the like as a material, a compound semiconductor substrate of silicon germanium, gallium nitride, or the like, or a semiconductor substrate such as an SOI substrate can be used.

### [Formation of Conductive Layer 14]

An insulating layer 31 is formed over the substrate 11.

The insulating layer 31 functions as an interlayer insulating layer or a base insulating layer. As the insulating layer 31, an inorganic insulating film with relatively low permittivity such as silicon oxide, silicon oxynitride, silicon oxide to which fluorine is added, silicon oxide to which carbon is added, silicon oxide to which carbon and nitrogen are added, and porous silicon oxide can be used.

The insulating layer 31 is preferably deposited by a sputtering method or a PECVD method.

Next, a position of the insulating layer 31 where the conductive layer 14 is embedded is removed by etching, so that a groove portion is formed. Specifically, a resist mask is formed over the insulating layer 31 and a portion not covered with the resist mask is removed by etching, so that the groove portion is formed.

Next, a conductive film to be the conductive layer 14 is formed to fill the groove portion, and then planarization treatment is performed, whereby the conductive layer 14 embedded in the insulating layer 31 can be formed. A deposition method such as a sputtering method, a CVD method, or an ALD method can be used for the conductive layer 14.

### [Formation of Conductive Layer 24]

Next, the insulating layer 32 is formed over the insulating layer 31 and the conductive layer 14. The insulating layer 32 can be formed by a material and a method similar to those of the insulating layer 31. Then, a groove portion reaching the conductive layer 14 is formed in the insulating layer 32.

Then, the conductive layer 24 is formed to be embedded in the groove portion of the insulating layer 32. In the case where an oxide conductive film is used for the conductive layer 24, a sputtering method or an ALD method is preferably used for deposition. After that, planarization treatment is performed, so that the conductive layer 24 can be formed (FIG. 12A1 and FIG. 12A2).

Note that in the case where the conductive layer 24 is provided for preventing oxidation of the conductive layer 14, an effect can be obtained even when the conductive layer 24 is thinner than the conductive layer 14 (e.g., less than or equal to 30 nm, less than or equal to 20 nm, or less than or equal to 10 nm and greater than or equal to 2 nm). In that case, the conductive layer 14 is formed without using the insulating layer 32, whereby the structure illustrated in FIG. 5B as an example may be employed.

[Formation of Insulating Layer 29a, Insulating Layer 28, and Insulating Layer 29b]

Next, the insulating layer 29a, the insulating layer 28, and the insulating layer 29b are formed in this order over the conductive layer 24 and the insulating layer 32.

Here, insulating films used for the insulating layer 29a and the insulating layer 29b preferably have compositions or constituent elements different from that of an insulating film used for the insulating layer 28.

Since the insulating layer 28 is a film to be in contact with the semiconductor layer 21 later, an oxide film including the amount of oxygen large enough to be released by heating and including a small amount of hydrogen is preferably used. The insulating layer 28 can be formed by a deposition method such as a PECVD method, a sputtering method, or an ALD method, and is particularly preferably deposited by a sputtering method. In particular, without using a gas containing hydrogen and with using a gas containing oxygen as a deposition gas, the insulating layer 28 containing an extremely small amount of hydrogen and an excess amount of oxygen can be deposited.

### [Formation of Conductive Layer 25]

Next, a conductive film to be the conductive layer 25 is formed over the insulating layer 29b and then an unnecessary portion is removed by etching, whereby the conductive layer 25 is formed.

### [Formation of Opening 20]

Subsequently, a resist mask is formed over the conductive layer 25 and the insulating layer 29b and then parts of the conductive layer 25, the insulating layer 29b, the insulating layer 28, and the insulating layer 29a are etched, whereby the openings 20 reaching the conductive layer 24 is formed in the conductive layer 25, the insulating layer 29b, the insulating layer 28, and the insulating layer 29a (FIG. 12B1 and FIG. 12B2).

For the etching of the conductive layer 25, the insulating layer 29b, the insulating layer 28, and the insulating layer 29a, dry etching is used whereby the minute opening 20 can be formed.

### [Formation of Semiconductor Layer 21]

Next, a semiconductor film to be the semiconductor layer 21 is formed and an unnecessary portion is removed by etching, so that the island-shaped semiconductor layer 21 is formed (FIG. 12C1 and FIG. 12C2).

The semiconductor layer 21 is preferably formed to have a film whose thickness is as uniform as possible on the side surfaces of the insulating layer 28, the insulating layer 29a, the insulating layer 29b, and the conductive layer 25 in the opening 20. Therefore, the film formation is preferably performed using an ALD method.

As a specific example, a deposition method such as a thermal ALD (Atomic Layer Deposition) method or a PEALD (Plasma Enhanced ALD) method is preferably used. The thermal ALD method is preferable because of its capability of forming a film with extremely high step coverage. The PEALD method is preferable because of its capability of forming a film at low temperatures, in addition to its capability of forming a film with high step coverage.

For example, in the case where a metal oxide is used for the semiconductor layer 21, the semiconductor layer 21 can be deposited by an ALD method using a precursor containing a constituent metal element and an oxidizer.

For example, in the case where an In—Ga—Zn oxide film is formed, three precursors, a precursor containing indium, a precursor containing gallium, and a precursor containing zinc can be used. Alternatively, two precursors, a precursor containing indium and a precursor containing gallium and zinc may be used.

As the precursor containing indium, triethylindium, tris(2,2,6,6-tetramethyl-3,5-heptanedionato)indium, cyclopentadienylindium, indium(III) chloride, or the like can be used.

As the precursor containing gallium, trimethylgallium, triethylgallium, gallium trichloride, tris(dimethylamide)gallium, gallium(III) acetylacetonate, tris(2,2,6,6-tetramethyl-3,5-heptanedionato)gallium, dimethylchlorogallium, diethylchlorogallium, gallium(III) chloride, or the like can be used.

As the precursor containing zinc, dimethylzinc, diethylzinc, bis(2,2,6,6-tetramethyl-3,5-heptanedionato)zinc, zinc chloride, or the like can be used.

Ozone, oxygen, water, or the like can be used as the oxidizer, for example.

As a method for controlling the composition of a film to be obtained, adjusting the flow rate ratio of source gases, the flowing time of the source gases, the order in which the source gases flow, or the like is given. By adjusting these, a film whose composition is continuously changed can be formed. Furthermore, films having different compositions can be formed successively.

Heat treatment may be performed after the film formation of the semiconductor film to be the semiconductor layer 21. By the heat treatment, water and hydrogen contained in the semiconductor film can be reduced and oxygen can be supplied from the insulating layer 28. Note that the heat treatment may be performed after the semiconductor film is processed.

Note that in the case where the opening 20 can be sufficiently covered, for the semiconductor layer 21, not limited to an ALD method, another film formation method can be used. For example, a sputtering method is preferably used because a film with a low hydrogen content can be obtained relatively easily.

### [Formation of Insulating Layer 22]

Next, the insulating layer 22 is formed to cover the conductive layer 25, the semiconductor layer 21, and the insulating layer 29b (FIG. 13A1 and FIG. 13A2.

Like the semiconductor layer 21, the insulating layer 22 is preferably formed by a deposition method with high step coverage and is preferably formed by an ALD method. Note that in the case where the semiconductor layer 21 positioned in the opening 20 can be sufficiently covered, the insulating layer 22 may be formed by a method other than an ALD method, such a deposition method as a PECVD method or a sputtering method.

### [Formation of Conductive Layer 23]

Next, a conductive film to be the conductive layer 23 is formed to cover the insulating layer 22 and an unnecessary portion is removed by etching, whereby the island-shaped conductive layer 23 is formed (FIG. 13B1 and FIG. 13B2).

Like the semiconductor layer 21 and the insulating layer 22, the conductive layer 23 is preferably formed by a deposition method with high step coverage and is preferably formed by an ALD method. A thermal CVD method can also be used. Note that in the case where the insulating layer 22 positioned in the opening 20 can be sufficiently covered, the conductive layer 23 may be formed by a method other than an ALD method, such a deposition method as a sputtering method.

### [Formation of Insulating Layer 33, Insulating Layer 39, and Insulating Layer 34]

Next, the insulating layer 33, the insulating layer 39, and the insulating layer 34 are sequentially formed to cover the conductive layer 23 and the insulating layer 22.

The insulating layer 33 and the insulating layer 34 can be formed using a material and a method similar to those of the insulating layer 31, for example. Since the insulating layer 39 functions as an etching stopper in the etching of the insulating layer 34, a film having a composition different from that of the insulating layer 34 is preferably used.

As the insulating layer 33, a film that contains a small amount of hydrogen and contains a large amount of oxygen as the one in the insulating layer 28 is preferably used. When such an insulating layer 33 is provided to be in contact with the insulating layer 22, oxygen can be supplied from the insulating layer 33 to the semiconductor layer 21 through the insulating layer 22 owing to heat applied during the manufacturing process.

### [Formation of Conductive Layer 13]

Next, first etching for forming an opening reaching the conductive layer 23 is performed on the insulating layer 34, the insulating layer 39, and the insulating layer 33. The opening is provided at a position overlapping with the opening 20. The opening corresponds to a portion between the conductive layer 13 and the conductive layer 23 to be in contact with each other later.

Next, second etching is performed on the insulating layer 34 to form a groove where the conductive layer 13 is to be embedded. After the second etching, the insulating layer 39 functioning as an etching stopper is exposed at the bottom portion of the groove. At this time, the groove is formed so that the opening is positioned inside the groove in a plan view.

After that, a conductive film to be the conductive layer 13 is formed to fill the opening formed by the first etching and the groove formed by the second etching, and then planarization treatment is performed until the top surface of the insulating layer 34 is exposed, whereby the conductive layer 13 can be formed (FIG. 13C1 and FIG. 13C2). For the film formation of the conductive film, a plating method is preferably used.

Note that when the top surface of the conductive layer 23 is exposed after the first etching, the conductive layer 23 might be damaged in the second etching. In that case, a thin film functioning as an etching stopper is preferably provided between the conductive layer 23 and the insulating layer 33, and the insulating layer 34, the insulating layer 39, and the insulating layer 33 are preferably etched to leave the thin film in the first etching. Thus, the conductive layer 23 can be prevented from being exposed at the time of the second etching. Note that the thin film may be removed by etching using the insulating layer 39 as a mask after the second etching and before the film formation of the conductive film to be the conductive layer 13.

Through the above process, the transistor 10 can be fabricated.

### Modification Example

A structure example of a transistor whose structure is different from the above will be described below.

In the above description, a structure in which a semiconductor layer is provided along the side surface of the insulating layer in the opening provided in the insulating layer and the like is described. A structure in which a semiconductor layer is provided along a side surface of a groove portion (slit) provided in an insulating layer and the like, instead of an opening, will be described below.

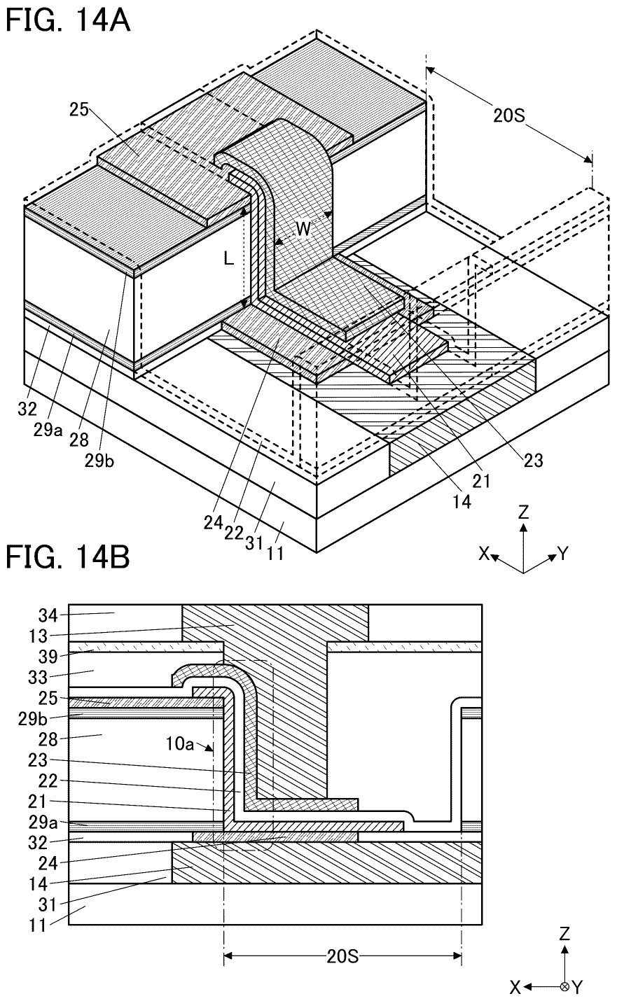

FIG. 14A is a schematic perspective view of a region including the transistor 10a. In FIG. 14, some components (e.g., the insulating layer 22) are outlined only by dashed lines, and other components (e.g., the conductive layer 13) are not illustrated. FIG. 14A illustrates an X-axis, a Y-axis, and a Z-axis for easy understanding of directions. FIG. 14B illustrates an X-Z cross section of a region including the transistor 10a.

The insulating layer 29a, the insulating layer 28, and the insulating layer 29b are provided with a slit 20S parallel to the Y direction. The conductive layer 24 and the insulating layer 32 are provided on the bottom portion of the slit 20S. The conductive layer 25 is provided over the insulating layer 29b and an end portion on the slit 20S side is processed to be aligned with the insulating layer 29b and the like.

The semiconductor layer 21 is provided to be in contact with the top surface of the conductive layer 25, the side surface of the insulating layer 29b, the side surface of the insulating layer 28, the side surface of the insulating layer 29a, and the top surface of the conductive layer 24 in the slit 20S. Part of the semiconductor layer 21 includes a portion in contact with the insulating layer 32 in the slit 20S.

The insulating layer 33 is provided to cover the insulating layer 29b, the conductive layer 25, the semiconductor layer 21, the insulating layer 32, and the like. In FIG. 14A, in addition to the outline of the insulating layer 22, part of the outline of a plane parallel to a side surface of the semiconductor layer 21 along the X direction is denoted by a dashed line.

The conductive layer 23 is provided over the insulating layer 22. The conductive layer 23 includes a portion overlapping with the semiconductor layer 21.

In the slit 20S, the semiconductor layer 21 includes a portion in contact with the side surface of the insulating layer 28. In the slit 20S, the insulating layer 22 includes a portion facing the side surface of the insulating layer 28 with the semiconductor layer 21 therebetween. In the slit 20S, the conductive layer 23 includes a portion facing the side surface of the insulating layer 28 with the insulating layer 22 and the semiconductor layer 21 therebetween. In the slit 20S, an interface between the semiconductor layer 21 and the insulating layer 28, an interface between the semiconductor layer 21 and the insulating layer 22, and an interface between the insulating layer 22 and the conductive layer 23 include portions where they are parallel to one another.

The insulating layer 33 is provided over the insulating layer 22 and the conductive layer 23 to fill part of the slit 20S, and the insulating layer 39 and the insulating layer 34 are provided over the insulating layer 33. The conductive layer 13 in contact with the conductive layer 23 is provided to be embedded in the insulating layer 34, the insulating layer 39, and the insulating layer 33.

As illustrated in FIG. 14A, the channel width W of the transistor 10a can be regarded as the width of a portion in the Y direction where the semiconductor layer 21 and the conductive layer 23 are stacked in a portion along a side surface of the insulating layer 33 in the slit 20S. Thus, the channel width W can be freely changed by designing, so the degree of freedom in designing is increased. Moreover, a transistor with a small channel length W can be fabricated as compared with the case where an opening is used. Note that as in Structure example 1 and the like, the channel length L of the transistor 10a can be regarded as the distance between a portion of the semiconductor layer 21 in contact with the conductive layer 25 and a portion of the semiconductor layer 21 in contact with the conductive layer 24.

The above is the description of the modification example.

### Embodiment 2

In this embodiment, a structure example of a display device to which the semiconductor device of one embodiment of the present invention can be applied will be described.

Since the semiconductor device of one embodiment of the present invention can be made extremely minute, the display device to which the semiconductor device of one embodiment of the present invention is applied can be a display device with extremely high resolution. For example, display devices of one embodiment of the present invention can be used for display portions of information terminal devices (wearable devices) such as wristwatch-type and bracelet-type information terminal devices and display portions of wearable devices that can be worn on a head (HMD: Head Mounted Display), such as a VR device like a head-mounted display and a glasses-type AR device.

### [Display Module]

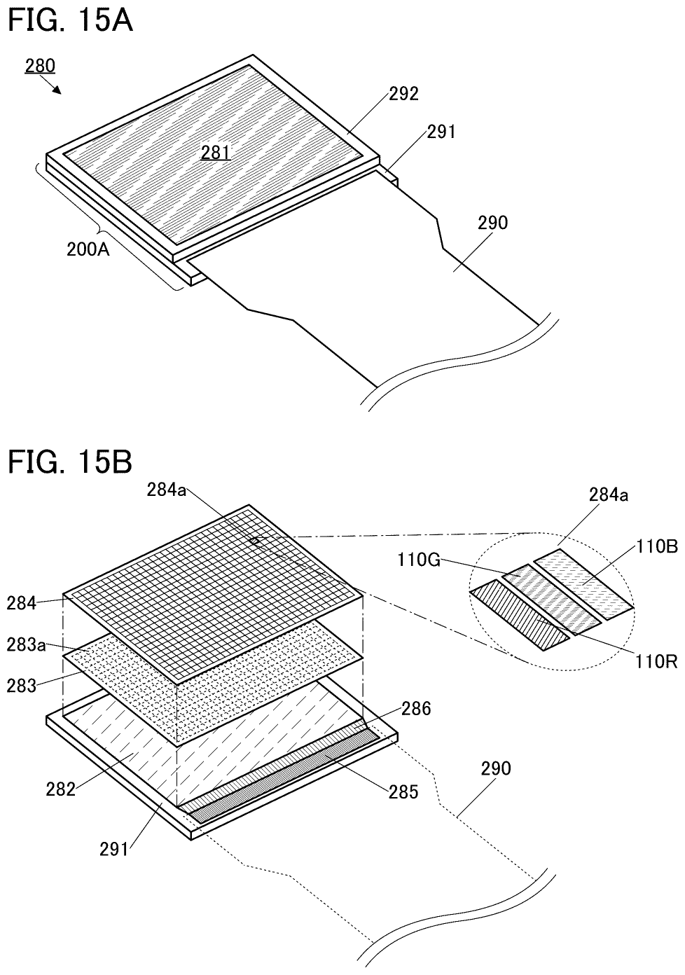

FIG. 15A is a perspective view of a display module 280. The display module 280 includes a display device 200A and an FPC 290. Note that a display panel included in the display module 280 is not limited to the display device 200A and may be a display device 200B or a display device 200C described later.

The display module 280 includes a substrate 291 and a substrate 292. The display module 280 includes a display portion 281. The display portion 281 is a region where an image is displayed.

FIG. 15B is a perspective view schematically illustrating a structure on the substrate 291 side. Over the substrate 291, a circuit portion 282, a pixel circuit portion 283 over the circuit portion 282, and a pixel portion 284 over the pixel circuit portion 283 are stacked. A terminal portion 285 to be connected to the FPC 290 is provided in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side of FIG. 15B. The pixel 284a includes a light-emitting element 110R that emits red light, a light-emitting element 110G that emits green light, and a light-emitting element 110B that emits blue light.

The pixel circuit portion 283 includes a plurality of pixel circuits 283a arranged periodically. One pixel circuit 283a is a circuit that controls light emission of three light-emitting devices included in one pixel 284a. One pixel circuit 283a may be provided with three circuits each of which controls light emission of one light-emitting device. For example, the pixel circuit 283a can include at least one selection transistor, one current control transistor (driving transistor), and a capacitor for one light-emitting device. In this case, a gate signal is input to a gate of the selection transistor, and a source signal is input to a source of the selection transistor. Thus, an active-matrix display panel is achieved.

The circuit portion 282 includes a circuit driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like. In addition, a transistor provided in the circuit portion 282 may constitute part of the pixel circuit 283a. That is, the pixel circuit 283a may be constituted by a transistor included in the pixel circuit portion 283 and a transistor included in the circuit portion 282.

The FPC 290 functions as a wiring for supplying a video signal, a power supply potential, and the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (the effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have extremely high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a VR device such as a head-mounted display or a glasses-type AR device. For example, even with a structure in which the display portion of the display module 280 is seen through a lens, pixels of the extremely-high-resolution display portion 281 included in the display module 280 are prevented from being perceived when the display portion is enlarged by the lens, so that display providing a high sense of immersion can be performed. Without being limited thereto, the display module 280 can be suitably used for an electronic device including a relatively small display portion. For example, the display module 280 can be suitably used for a display portion of a wearable electronic device, such as a wrist watch.

### [Display Device 200A]

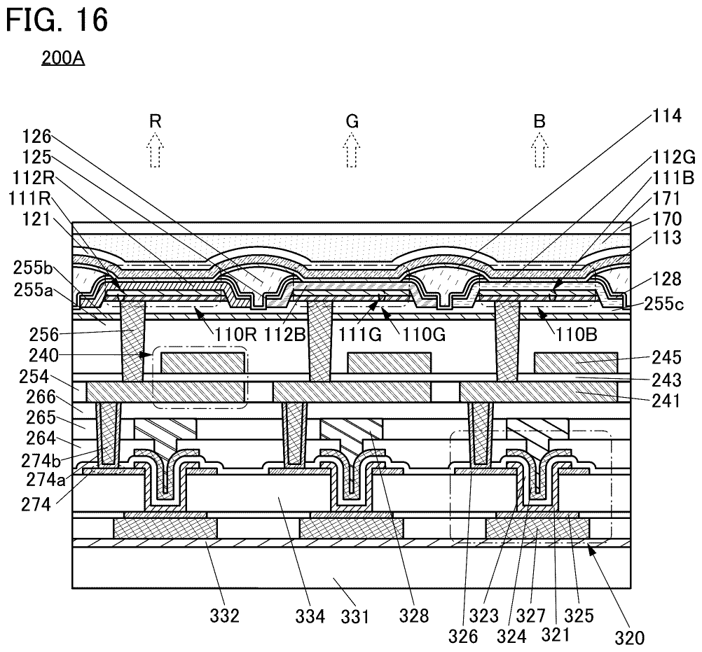

The display device 200A illustrated in FIG. 16 includes a substrate 331, the light-emitting element 110R, the light-emitting element 110G, the light-emitting element 110B, a capacitor 240, and a transistor 320.

The substrate 331 corresponds to the substrate 291 in FIG. 15A.

The transistor 320 is a vertical-channel transistor that an oxide semiconductor is used in a semiconductor layer where a channel is formed. The transistor 320 includes a semiconductor layer 321, an insulating layer 323, a conductive layer 324, a conductive layer 325, a conductive layer 326, and the like.

As the transistor 320, any of the transistors described in Embodiment 1 can be used.

An insulating layer 332 is provided over the substrate 331. The insulating layer 332 functions as a barrier layer that prevents diffusion of impurities such as water and hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

A conductive layer 327 is provided over the insulating layer 332, and the conductive layer 325 is provided over the conductive layer 327. An insulating layer 334 is provided over the conductive layer 325, and the conductive layer 326 is provided over the insulating layer 334. An opening is provided in the insulating layer 334 and the conductive layer 326, and the semiconductor layer 321 is provided in the opening. An insulating layer 264 is provided to cover the semiconductor layer 321 and the conductive layer 326, and the insulating layer 323 and the conductive layer 324 are stacked in this order in an opening provided in the insulating layer 264. The insulating layer 264 and an insulating layer 265 are stacked to cover the insulating layer 323 and the conductive layer 324, and a conductive layer 328 in contact with the conductive layer 324 is embedded in the insulating layer 264 and the insulating layer 265. An insulating layer 266 is provided over the insulating layer 265 and the conductive layer 328.

The insulating layer 264, the insulating layer 265, and the insulating layer 266 function as interlayer insulating layers. A barrier layer that prevents diffusion of impurities such as water and hydrogen from the insulating layer 265 or the like into the transistor 320 may be provided between the insulating layer 266 and the insulating layer 265. As the barrier layer, an insulating film similar to the insulating layer 332 can be used.

A plug 274 electrically connected to one of the conductive layers 326 is provided to be embedded in the insulating layer 266, the insulating layer 265, the insulating layer 264, and the insulating layer 323. Here, the plug 274 preferably includes a conductive layer 274a covering a side surface of an opening formed in the insulating layer 266, the insulating layer 265, the insulating layer 264, and the insulating layer 323 and part of the top surface of the conductive layer 326, and a conductive layer 274b in contact with the top surface of the conductive layer 274a. For the conductive layer 274a, a conductive material in which hydrogen and oxygen are less likely to diffuse is preferably used.

In addition, the capacitor 240 is provided over the insulating layer 266. The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 266 and is embedded in an insulating layer 254. The conductive layer 241 is electrically connected to the conductive layer 326 in the transistor 320 through the plug 274. The insulating layer 243 is provided to cover the conductive layer 241. The conductive layer 245 is provided in a region overlapping with the conductive layer 241 with the insulating layer 243 therebetween.

An insulating layer 255a is provided to cover the capacitor 240, an insulating layer 255b is provided over an insulating layer 255a, and the insulating layer 255c is provided over the insulating layer 255b.

An inorganic insulating film can be suitably used for each of the insulating layer 255a, the insulating layer 255b, and the insulating layer 255c. For example, it is preferable that a silicon oxide film be used for each of the insulating layer 255a and the insulating layer 255c and that a silicon nitride film be used for the insulating layer 255b. This enables the insulating layer 255b to function as an etching protective film. Although this embodiment shows an example where the insulating layer 255c is partly etched and a depressed portion is formed, the depressed portion is not necessarily provided in the insulating layer 255c.

The light-emitting element 110R, the light-emitting element 110G, and the light-emitting element 110B are provided over the insulating layer 255c. Details of the light-emitting element 110R, the light-emitting element 110G, and the light-emitting element 110B will be described in Embodiment 3.

The light-emitting element 110R includes a pixel electrode 111R, an organic layer 112R, a common layer 114, and a common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can be also referred to as an EL layer and includes at least a layer containing a light-emitting organic compound (a light-emitting layer).

In the display device 200A, since the light-emitting devices of different colors are separately formed, a change in chromaticity between light emission at low luminance and light emission at high luminance is small. Furthermore, since the organic layers 112R, 112G, and 112B are apart from each other, crosstalk generated between adjacent subpixels can be inhibited while the display panel has high resolution. It is thus possible to achieve a display panel that has high definition and high display quality.

In a region between adjacent light-emitting elements, an insulating layer 125, a resin layer 126, and a layer 128 are provided.

The pixel electrode 111R, the pixel electrode 111G, and the pixel electrode 111B of the light-emitting elements are each electrically connected to the conductive layer 326 in the transistor 320 through a plug 256 that is embedded in the insulating layer 255a, the insulating layer 255b and the insulating layer 255c, the conductive layer 241 that is embedded in the insulating layer 254, and the plug 274. The top surface of the insulating layer 255c and the top surface of the plug 256 are level or substantially level with each other. A variety of conductive materials can be used for the plugs.

In addition, a protective layer 121 is provided over the light-emitting elements 110R, 110G, and 110B. A substrate 170 is attached onto the protective layer 121 with an adhesive layer 171.

An insulating layer covering an end portion of a top surface of the pixel electrode 111 is not provided between two adjacent pixel electrodes 111. Thus, the distance between adjacent light-emitting elements can be extremely reduced. Accordingly, the display device can have a high resolution or a high definition.

### [Display Device 200B]

A display device whose structure is partly different from that of the above will be described below. Note that the above description can be referred to for portions common to those described above, and the description is omitted in some cases.

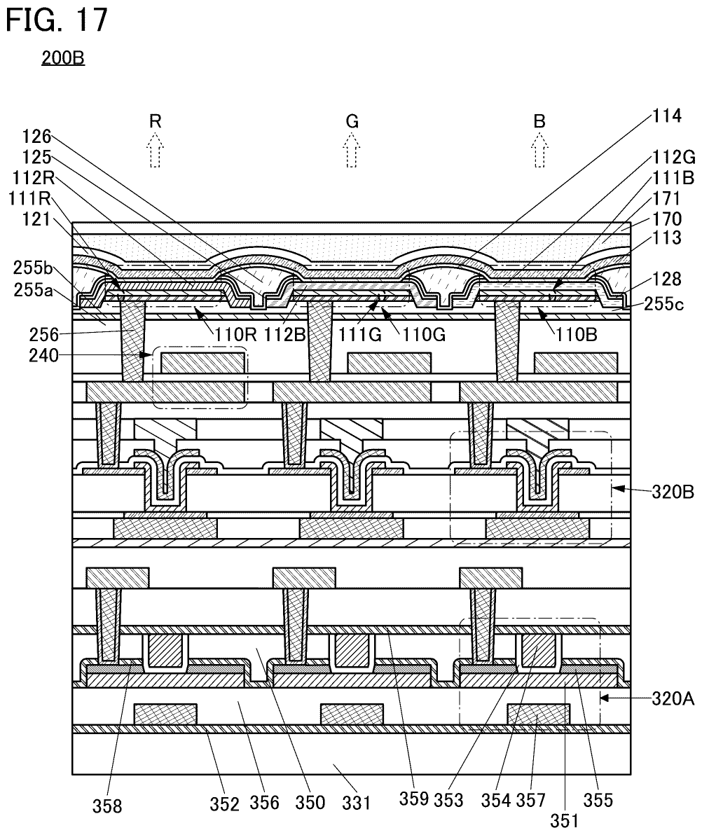

The display device 200B illustrated in FIG. 17 is an example in which a transistor 320A, which is a planar transistor whose semiconductor layer is formed on a plane, and a transistor 320B, which is a vertical-channel transistor, are stacked. The transistor 320B has a structure similar to that of the transistor 320 in the display device 200A.

The transistor 320A includes a semiconductor layer 351, an insulating layer 353, a conductive layer 354, a pair of conductive layers 355, an insulating layer 356, and a conductive layer 357.

An insulating layer 352 is provided over the substrate 331. The insulating layer 352 functions as a barrier layer that prevents diffusion of impurities such as water and hydrogen from the substrate 331 into the transistor 320 and release of oxygen from the semiconductor layer 351 to the insulating layer 352 side. As the insulating layer 352, for example, a film through which hydrogen or oxygen is less likely to diffuse than in a silicon oxide film, such as an aluminum oxide film, a hafnium oxide film, or a silicon nitride film, can be used.

The conductive layer 357 is provided over the insulating layer 352, and the insulating layer 356 is provided to cover the conductive layer 357. The conductive layer 357 functions as a first gate electrode of the transistor 320A, and part of the insulating layer 356 functions as a first gate insulating layer. An oxide insulating film such as a silicon oxide film is preferably used as at least a portion of the insulating layer 356 that is in contact with the semiconductor layer 351. The top surface of the insulating layer 356 is preferably planarized.

The semiconductor layer 351 is provided over the insulating layer 356. The semiconductor layer 351 preferably includes a metal oxide (also referred to as an oxide semiconductor) film exhibiting semiconductor characteristics. The pair of conductive layers 355 is provided over and in contact with the semiconductor layer 351 and functions as a source electrode and a drain electrode.

An insulating layer 358 and an insulating layer 350 are provided to cover the top and side surfaces of the pair of conductive layers 355, a side surface of the semiconductor layer 351, and the like. The insulating layer 358 functions as a barrier layer that prevents diffusion of impurities such as water and hydrogen and the like into the semiconductor layer 351 and release of oxygen from the semiconductor layer 351. As the insulating layer 358, an insulating film similar to the insulating layer 352 can be used.

An opening reaching the semiconductor layer 351 is provided in the insulating layer 358 and the insulating layer 350. The insulating layer 353 that is in contact with a top surface of the semiconductor layer 351 and the conductive layer 354 are embedded in the opening. The conductive layer 354 functions as a second gate electrode, and the insulating layer 353 functions as a second gate insulating layer.

The top surface of the conductive layer 354, the top surface of the insulating layer 353, and the top surface of the insulating layer 350 are planarized so as to be level or substantially level with each other, and an insulating layer 359 are provided to cover these layers. The insulating layer 359 functions as a barrier layer that prevents diffusion of impurities such as water and hydrogen into the transistor 320. As the insulating layer 359, an insulating film similar to the insulating layer 352 can be used.

The transistor 320 has a structure in which the semiconductor layer where a channel is formed is provided between two gates. The two gates may be connected to each other and supplied with the same signal to drive the transistor. Alternatively, a potential for controlling the threshold voltage may be supplied to one of the two gates and a potential for driving may be supplied to the other to control the threshold voltage of the transistor.

### [Display Device 200C]

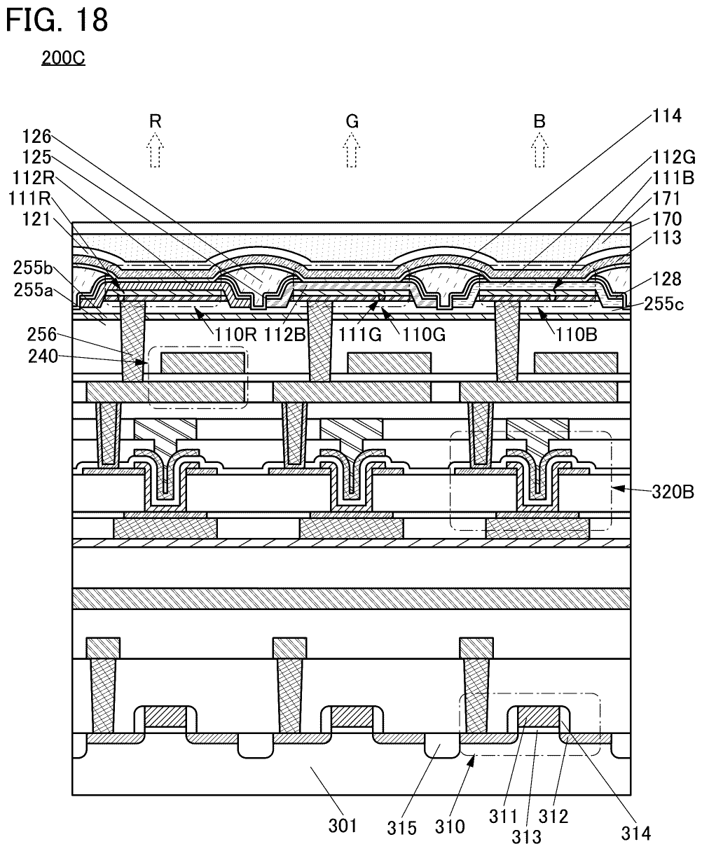

The display device 200C illustrated in FIG. 18 has a structure where a transistor 310 in which a channel is formed in a semiconductor substrate and a vertical-channel transistor 320 are stacked.

The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover a side surface of the conductive layer 311.

An element isolation layer 315 is provided between two adjacent transistors 310 to be embedded in the substrate 301.

At least part of this embodiment can be implemented in combination with the other embodiments described in this specification as appropriate.

### Embodiment 3

In this embodiment, structure examples of a display device that can be used as a display device manufactured using the transistor of one embodiment of the present invention will be described. The display device described below as an example can be used for the pixel portion 284 in Embodiment 2 and the like.

One embodiment of the present invention is a display device including a light-emitting element (also referred to as a light-emitting device). The display device includes two or more pixels of different emission colors. Each of the pixels includes a light-emitting element. The light-emitting elements each include a pair of electrodes and an EL layer therebetween. The light-emitting elements are preferably organic EL elements (organic electroluminescent elements). The two or more light-emitting elements of different emission colors include EL layers formed using different light-emitting materials. For example, when three kinds of light-emitting elements that emit red (R), green (G), and blue (B) light are included, a full-color display device can be achieved.

In the case of manufacturing a display device including a plurality of light-emitting elements that emit light of different emission colors, at least layers containing light-emitting materials (light-emitting layers) each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a deposited film due to vapor scattering, for example; accordingly, it is difficult to achieve a high resolution and a high aperture ratio of the display device. In addition, the outline of the layer might blur during evaporation, so that the thickness of an end portion might be reduced. That is, the thickness of an island-shaped light-emitting layer might vary from place to place. In addition, in the case of manufacturing a display device with a large size, high definition, or high resolution, a manufacturing yield might be reduced because of low dimensional accuracy of the metal mask and deformation due to heat or the like. Thus, a measure has been taken for a pseudo increase in resolution (also referred to as pixel density) by employing a unique pixel arrangement such as a PenTile arrangement.

Note that in this specification and the like, the term “island shape” refers to a state where two or more layers formed using the same material in the same step are physically separated from each other. For example, “island-shaped light-emitting layer” means a state where the light-emitting layer and its adjacent light-emitting layer are physically separated from each other.

In one embodiment of the present invention, fine patterning of EL layers is performed by photolithography without using a shadow mask such as a fine metal mask (an FMM). Accordingly, it is possible to achieve a display device with high resolution and a high aperture ratio, which has been difficult to achieve. Moreover, since the EL layers can be formed separately, it is possible to achieve a display device that performs extremely clear display with high contrast and high display quality. Note that fine patterning of the EL layers may be performed using both a metal mask and photolithography, for example.

In addition, part or the whole of an EL layer can be physically divided. This can inhibit leakage current flowing between adjacent light-emitting elements through a layer shared by the light-emitting elements (also referred to as a common layer). This can prevent crosstalk due to unintended light emission, so that a display device with extremely high contrast can be achieved. In particular, a display device having high current efficiency at low luminance can be achieved.

In one embodiment of the present invention, the display device can also be obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, part or the whole of each EL layer may be divided by photolithography. Thus, leakage current through the common layer is inhibited; accordingly, a high-contrast display device can be achieved. In particular, when an element has a tandem structure in which a plurality of light-emitting layers are stacked with a highly conductive intermediate layer therebetween, leakage current through the intermediate layer can be effectively prevented, so that a display device with high luminance, high resolution, and high contrast can be achieved.

In the case where the EL layer is processed by a photolithography method, part of the light-emitting layer is sometimes exposed to cause deterioration. Thus, an insulating layer covering at least a side surface of the island-shaped light-emitting layer is preferably provided. The insulating layer may cover part of a top surface of an island-shaped EL layer. For the insulating layer, a material having a barrier property against water and oxygen is preferably used. For example, an inorganic insulating film in which water or oxygen is less likely to diffuse can be used. This can inhibit degradation of the EL layer and can achieve a highly reliable display device.

Moreover, between two adjacent light-emitting elements, there is a region (a depressed portion) where none of the EL layers of the light-emitting elements can be provided. In the case where a common electrode or a common electrode and a common layer are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a local gap positioned between two adjacent light-emitting elements is preferably filled with a resin layer functioning as a planarization film (also referred to as LFP: Local Filling Planarization). The resin layer has a function of the planarization film. This structure can inhibit disconnection of the common layer or the common electrode and can achieve a highly reliable display device.

More specific structure examples of the display device of one embodiment of the present invention will be described below with reference to drawings.

### Structure Example 1

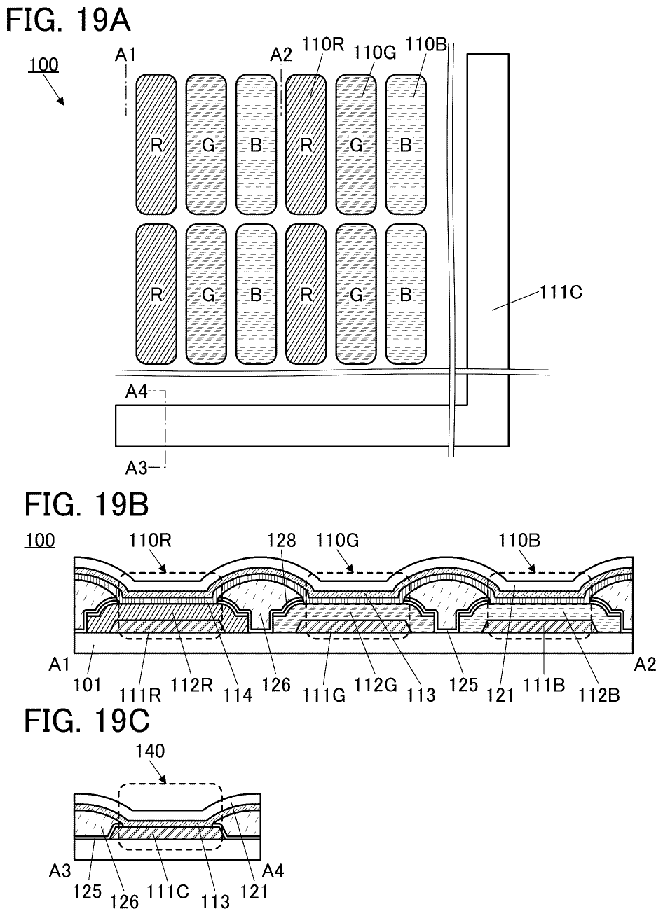

FIG. 19A illustrates a schematic top view of a display device 100 of one embodiment of the present invention. The display device 100 includes, over a substrate 101, a plurality of light-emitting elements 110R exhibiting red, a plurality of light-emitting elements 110G exhibiting green, and a plurality of light-emitting elements 110B exhibiting blue. In FIG. 19A, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 19A illustrates what is called a stripe arrangement, in which the light-emitting elements of the same color are arranged in one direction. Note that an arrangement method of the light-emitting elements is not limited thereto; an arrangement method such as an S-stripe arrangement, a delta arrangement, a Bayer arrangement, or a zigzag arrangement may be employed, or a PenTile arrangement, a diamond arrangement, or the like can also be used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As examples of a light-emitting substance contained in the EL element, a substance that emits fluorescent light (a fluorescent material), a substance that emits phosphorescent light (a phosphorescent material), and a substance that exhibits thermally activated delayed fluorescence (a thermally activated delayed fluorescent (TADF) material) can be given. As the light-emitting substance contained in the EL element, not only an organic compound but also an inorganic compound (a quantum dot material or the like) can be used.

FIG. 19A also illustrates a connection electrode 111C that is electrically connected to the common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region or may be provided along two or more sides of the outer periphery of the display region. That is, in the case where the display region has a rectangular top surface shape, the top surface of the connection electrode 111C can have a band shape (a rectangle), an L shape, a U shape (a square bracket shape), a quadrangular shape, or the like.

FIG. 19B and FIG. 19C are schematic cross-sectional views respectively corresponding to the dashed-dotted line A1-A2 and the dashed-dotted line A3-A4 in FIG. 19A. FIG. 19B illustrates a schematic cross-sectional view of the light-emitting element 110R, the light-emitting element 110G, and the light-emitting element 110B, and FIG. 19C illustrates a schematic cross-sectional view of a connection portion 140 where the connection electrode 111C and the common electrode 113 are connected to each other.

The light-emitting element 110R includes the pixel electrode 111R, the organic layer 112R, the common layer 114, and the common electrode 113. The light-emitting element 110G includes the pixel electrode 111G, the organic layer 112G, the common layer 114, and the common electrode 113. The light-emitting element 110B includes the pixel electrode 111B, the organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 has a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as one continuous layer shared by the light-emitting elements. A conductive film having a property of transmitting visible light is used for either the pixel electrodes or the common electrode 113, and a conductive film having a reflective property is used for the other. When the pixel electrodes have a light-transmitting property and the common electrode 113 has a reflective property, a bottom-emission display device can be obtained. In contrast, when the pixel electrodes have a reflective property and the common electrode 113 has alight-transmitting property, atop-emission display device can be obtained. Note that when both the pixel electrodes and the common electrode 113 have a light-transmitting property, a dual-emission display device can also be obtained.

The protective layer 121 is provided over the common electrode 113 to cover the light-emitting element 110R, the light-emitting element 110G, and the light-emitting element 110B. The protective layer 121 has a function of preventing diffusion of impurities such as water into each light-emitting element from the above.

An end portion of the pixel electrode 111 preferably has a tapered shape. In the case where the end portion of the pixel electrode 111 has a tapered shape, the organic layer 112 that is provided along the end portion of the pixel electrode 111 can also have a tapered shape. When the end portion of the pixel electrode 111 has a tapered shape, coverage with the organic layer 112 provided beyond the end portion of the pixel electrode 111 can be improved. Furthermore, a side surface of the pixel electrode 111 preferably has a tapered shape, in which case a foreign matter (also referred to as dust or particles, for example) in the manufacturing process is easily removed by processing such as cleaning.

Note that in this specification and the like, a tapered shape refers to a shape such that at least part of a side surface of a component is inclined to a substrate surface. For example, a tapered shape preferably includes a region where the angle between the inclined side surface and the substrate surface (such an angle is also referred to as a taper angle) is less than 90°.

The organic layer 112 is processed into an island shape by a photolithography method. Thus, an angle formed between a top surface and a side surface of an end portion of the organic layer 112 is approximately 90°. By contrast, an organic film formed using an FMM (Fine Metal Mask) or the like has a thickness that tends to gradually decrease with decreasing distance to an end portion, and has a top surface forming a slope in an area extending greater than or equal to 1 μm and less than or equal to 10 μm to the end portion, for example; thus, such an organic film has a shape whose top surface and side surface are difficult to distinguish from each other.

The insulating layer 125, the resin layer 126, and the layer 128 are included between two adjacent light-emitting elements.

Between two adjacent light-emitting elements, side surfaces of the organic layers 112 are provided to face each other with the resin layer 126 therebetween. The resin layer 126 is positioned between the two adjacent light-emitting elements and is provided to bury end portions of the organic layers 112 and a region between the two organic layers 112. The resin layer 126 has a top surface with a smooth convex shape and the common layer 114 and the common electrode 113 are provided to cover the top surface of the resin layer 126.

The resin layer 126 functions as a planarization film that fills a step positioned between two adjacent light-emitting elements. Providing the resin layer 126 can prevent a phenomenon in which the common electrode 113 is divided by a step at an end portion of the organic layer 112 (such a phenomenon is also referred to as disconnection) from occurring and the common electrode 113 over the organic layer 112 from being insulated. The resin layer 126 can also be referred to as an LFP (Local Filling Planarization) layer.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used as the photosensitive resin. As the photosensitive resin, a positive material or a negative material can be used.

The resin layer 126 may contain a material absorbing visible light. For example, the resin layer 126 itself may be made of a material absorbing visible light, or the resin layer 126 may contain a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided to be in contact with a side surface of the organic layer 112. In addition, the insulating layer 125 is provided to cover an upper end portion of the organic layer 112. Furthermore, part of the insulating layer 125 is provided to be in contact with the top surface of the substrate 101.

The insulating layer 125 is positioned between the resin layer 126 and the organic layer 112 and functions as a protective film for preventing contact between the resin layer 126 and the organic layer 112. When the organic layer 112 and the resin layer 126 are in contact with each other, the organic layer 112 might be dissolved by an organic solvent or the like used at the time of forming the resin layer 126. Therefore, the insulating layer 125 is provided between the organic layer 112 and the resin layer 126, whereby the side surface of the organic layer 112 can be protected.

An insulating layer containing an inorganic material can be used as the insulating layer 125. For the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is employed for the insulating layer 125, it is possible to form the insulating layer 125 that has a small number of pinholes and has an excellent function of protecting the EL layer.

Note that in this specification and the like, oxynitride refers to a material that contains more oxygen than nitrogen in its composition, and nitride oxide refers to a material that contains more nitrogen than oxygen in its composition. For example, in the case where silicon oxynitride is described, it refers to a material that contains more oxygen than nitrogen in its composition, and in the case where silicon nitride oxide is described, it refers to a material that contains more nitrogen than oxygen in its composition.

The insulating layer 125 can be formed by a sputtering method, a CVD method, a PLD method, an ALD method, or the like. The insulating layer 125 is preferably formed by an ALD method that provides excellent coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked-layer film of an inorganic insulating film and an organic insulating film can also be used. For example, a structure in which an organic insulating film is sandwiched between a pair of inorganic insulating films is preferable. Furthermore, the organic insulating film preferably functions as a planarization film. This enables a top surface of the organic insulating film to be flat, which results in improved coverage with the inorganic insulating film thereover and a higher barrier property. Moreover, the top surface of the protective layer 121 is flat, which is preferable because the influence of an uneven shape due to a lower structure can be reduced in the case where a component (e.g., a color filter, an electrode of a touch sensor, a lens array, or the like) is provided above the protective layer 121.

FIG. 19C illustrates the connection portion 140 where the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 19C illustrates the connection portion 140 where the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, the common layer 114 can be formed to be thin using a material with sufficiently low electrical resistivity; thus, problems do not arise in many cases even when the common layer 114 is positioned in the connection portion 140. Accordingly, the common electrode 113 and the common layer 114 can be formed using the same shielding mask, so that manufacturing cost can be reduced.

### Structure Example 2

A display device whose structure is partly different from that of Structure example 1 described above is described below. Note that the above description can be referred to for the same portions as those in Structure example 1, and the description is omitted in some cases.

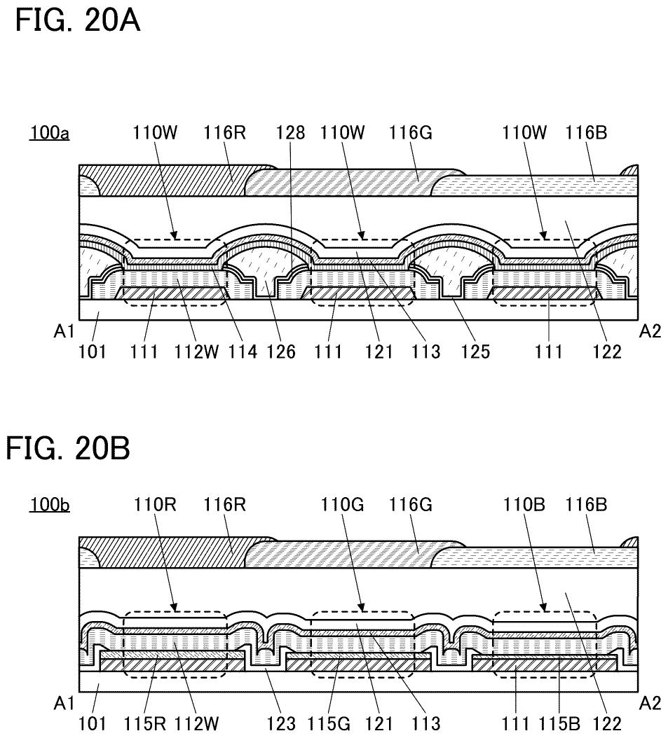

FIG. 20A illustrates a schematic cross-sectional view of a display device 100a. The display device 100a is different from the above-described display device 100 mainly in a structure of the light-emitting element and including a coloring layer.

The display device 100a includes a light-emitting element 110W emitting white light. The light-emitting element 110W includes the pixel electrode 111, an organic layer 112W, the common layer 114, and the common electrode 113. The organic layer 112W emits white light. For example, the organic layer 112W can contain two or more kinds of light-emitting materials emitting light of complementary colors. For example, the organic layer 112W can contain a light-emitting organic compound emitting red light, a light-emitting organic compound emitting green light, and a light-emitting organic compound emitting blue light. Alternatively, the organic layer 112W may contain a light-emitting organic compound emitting blue light and a light-emitting organic compound emitting yellow light.

The organic layer 112W is divided between two adjacent light-emitting elements 110W. Thus, a leakage current that flows between the adjacent light-emitting elements 110W through the organic layer 112W can be inhibited and crosstalk due to the leakage current can be inhibited. Accordingly, the display device can have high contrast and high color reproducibility.

An insulating layer 122 functioning as a planarization film is provided over the protective layer 121, and a coloring layer 116R, a coloring layer 116G, and a coloring layer 116B are provided over the insulating layer 122.

An organic resin film or an inorganic insulating film with a flat top surface can be used for the insulating layer 122. The insulating layer 122 is a formation surface on which the coloring layer 116R, the coloring layer 116G, and the coloring layer 116B are formed; thus, with a flat top surface of the insulating layer 122, the thickness of the coloring layer 116R or the like can be uniform and color purity of light extracted from each of the light-emitting devices can be increased. Note that if the thickness of the coloring layer 116R or the like is not uniform, the amount of light absorption varies depending on a region in the coloring layer 116R, which might decrease color purity.

### Structure Example 3

FIG. 20B illustrates a schematic cross-sectional view of a display device 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film reflecting visible light is used for the pixel electrode 111 and a film having both properties of reflecting and transmitting visible light is used for the common electrode 113, whereby a microcavity structure can be achieved. At this time, by adjusting the thicknesses of the conductive layer 115R, the conductive layer 115G, and the conductive layer 115B to obtain optimal optical path lengths, light obtained from the light-emitting element 110R, the light-emitting element 110G, and the light-emitting element 110B can be intensified light with different wavelengths even in the case where the organic layer 112 exhibiting white light emission is used.

Furthermore, the coloring layer 116R, the coloring layer 116G, and the coloring layer 116B are provided on the optical paths of the light-emitting element 110R, the light-emitting element 110G, and the light-emitting element 110B, respectively, whereby light with high color purity can be obtained.

An insulating layer 123 that covers an end portion of the pixel electrode 111 and an optical adjustment layer 115 is provided. An end portion of the insulating layer 123 preferably has a tapered shape. When the insulating layer 123 is provided, coverage with the organic layer 112W, the common electrode 113, the protective layer 121, and the like formed over the insulating layer 123 can be increased.

The organic layer 112W and the common electrode 113 are each provided as one continuous film shared by the light-emitting elements. Such a structure is preferable because the manufacturing process of the display device can be greatly simplified.

Here, the end portion of the pixel electrode 111 is preferably substantially perpendicular to the top surface of the substrate 101. This enables a steep portion to be formed on the surface of the insulating layer 123, and thus part of the organic layer 112W covering the steep portion can have a small thickness or part of the organic layer 112W can be separated. Accordingly, a leakage current generated between adjacent light-emitting elements through the organic layer 112W can be inhibited without processing the organic layer 112W by a photolithography method or the like.

The above is the description of the structure examples of the display devices.

At least part of this embodiment can be implemented in appropriate combination with the other embodiments described in this specification.

### Embodiment 4

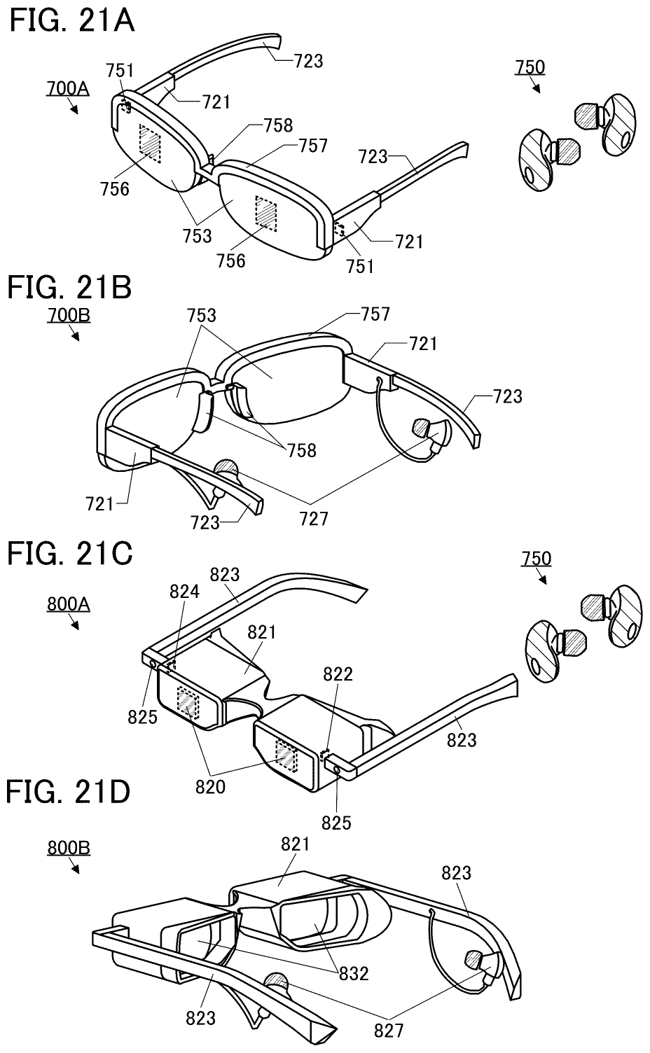

In this embodiment, electronic devices of one embodiment of the present invention will be described with reference to FIG. 21 to FIG. 23.

Electronic devices in this embodiment each include the display panel (display device) employing the transistor of one embodiment of the present invention in a display portion. The display device of one embodiment of the present invention can easily achieve higher resolution and higher definition and can achieve high display quality. Thus, the display device of one embodiment of the present invention can be used for display portions of a variety of electronic devices.

Examples of the electronic devices include a digital camera, a digital video camera, a digital photo frame, a cellular phone, a portable game machine, a portable information terminal, and an audio reproducing device, in addition to electronic devices with comparatively large screens, such as a television device, a desktop or laptop personal computer, a monitor for a computer or the like, digital signage, and a large game machine such as a pachinko machine.

In particular, the display panel of one embodiment of the present invention can have higher resolution, and thus can be suitably used for an electronic device having a comparatively small display portion. Examples of such an electronic device include wristwatch-type and bracelet-type information terminal devices (wearable devices) and wearable devices that can be worn on a head, such as a device for VR like a head-mounted display, a glasses-type device for AR, and a device for MR.

The definition of the display panel of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, a definition of 4K, 8K, or higher is preferable. In addition, the pixel density (resolution) of the display panel of one embodiment of the present invention is preferably higher than or equal to 100 ppi, further preferably higher than or equal to 300 ppi, still further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. With the use of such a display panel having one or both of high definition and high resolution, realistic sensation, sense of depth, and the like can be further increased. Furthermore, there is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, a flow rate, humidity, a gradient, oscillation, odor, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a storage medium.

Examples of wearable devices that can be worn on a head are described using FIG. 21A to FIG. 21D. These wearable devices have one or both of a function of displaying AR contents and a function of displaying VR contents. Note that the wearable devices may have a function of displaying SR or MR contents, in addition to AR and VR contents. The electronic device having a function of displaying contents of at least one of AR, VR, SR, MR, and the like enables the user to reach a higher level of immersion.

An electronic device 700A illustrated in FIG. 21A and an electronic device 700B illustrated in FIG. 21B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be employed as the display panels 751. Thus, the electronic devices can perform display with extremely high resolution.

The electronic device 700A and the electronic device 700B can each project images displayed on the display panels 751 onto display regions 756 of the optical members 753. Since the optical members 753 have a light-transmitting property, the user can see images displayed on the display regions that are superimposed on transmission images seen through the optical members 753. Thus, the electronic device 700A and the electronic device 700B are electronic devices capable of AR display.

In each of the electronic device 700A and the electronic device 700B, a camera capable of capturing images of the front side may be provided as the image capturing portion. Furthermore, when each of the electronic device 700A and the electronic device 700B is provided with an acceleration sensor such as a gyroscope sensor, the orientation of a user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable supplied with a video signal and a power supply potential can be connected may be provided.

In addition, each of the electronic device 700A and the electronic device 700B is provided with a battery so that charging can be performed wirelessly and/or by wire.

A touch sensor module may be provided in the housing 721. The touch sensor module has a function of detecting a touch on an outer surface of the housing 721. A tap operation, a slide operation, or the like by the user can be detected with the touch sensor module, so that various types of processing can be executed. For example, processing such as a pause or a restart of a moving image can be executed by a tap operation, and processing such as fast forward or fast rewind can be executed by a slide operation. In addition, the touch sensor module is provided in each of the two housings 721, so that the range of the operation can be increased.

A variety of touch sensors can be employed for the touch sensor module. For example, touch sensors of a variety of types such as a capacitive type, a resistive film type, an infrared type, an electromagnetic induction type, a surface acoustic wave type, and an optical type can be employed. In particular, a capacitive sensor or an optical sensor is preferably employed for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 21C and an electronic device 800B illustrated in FIG. 21D each include a pair of display portions 820, a housing 821, a communication portion 822, a pair of wearing portions 823, a control portion 824, a pair of image capturing portions 825, and a pair of lenses 832.

The display panel of one embodiment of the present invention can be employed for the display portions 820. Thus, the electronic devices can perform display with extremely high resolution. This enables the user to feel a high sense of immersion.

The display portions 820 are positioned inside the housing 821 so as to be seen through the lenses 832. Furthermore, when the pair of display portions 820 display different images, three-dimensional display using parallax can also be performed.

Each of the electronic device 800A and the electronic device 800B can be regarded as an electronic device for VR. The user who wears the electronic device 800A or the electronic device 800B can see images displayed on the display portions 820 through the lenses 832.

The electronic device 800A and the electronic device 800B each preferably include a mechanism for adjusting the lateral positions of the lenses 832 and the display portions 820 so that the lenses 832 and the display portions 820 are positioned optimally in accordance with the positions of the user's eyes. In addition, a mechanism for adjusting focus by changing the distance between the lenses 832 and the display portions 820 is preferably included.

The electronic device 800A or the electronic device 800B can be worn on the user's head with the wearing portions 823. Note that FIG. 21C and the like illustrate examples where the wearing portion 823 has a shape like a temple of glasses (also referred to as a joint or the like); however, one embodiment of the present invention is not limited thereto. The wearing portion 823 can have any shape with which the user can wear and may have a shape of a helmet or a band, for example.

The image capturing portion 825 has a function of obtaining external information. Data obtained by the image capturing portion 825 can be output to the display portions 820. An image sensor can be used for the image capturing portion 825. Moreover, a plurality of cameras may be provided to support a plurality of fields of view, such as a telescope field of view and a wide field of view.

Note that although an example where the image capturing portion 825 is included is shown here, a range sensor that is capable of measuring the distance to an object (hereinafter such a sensor is also referred to as a sensing portion) is provided. In other words, the image capturing portion 825 is one embodiment of the sensing portion. For the sensing portion, an image sensor or a distance image sensor such as LIDAR (Light Detection and Ranging) can be used, for example. By using images obtained by a camera and images obtained by the distance image sensor, more pieces of information can be obtained and a gesture operation with higher accuracy is possible.

The electronic device 800A may include a vibration mechanism that functions as bone-conduction earphones. For example, any one or more of the display portion 820, the housing 821, and the wearing portion 823 can include the vibration mechanism. Thus, without additionally requiring an audio device such as headphones, earphones, or a speaker, the user can enjoy a video and sound only by wearing the electronic device 800A.

The electronic device 800A and the electronic device 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 21A has a function of transmitting information to the earphones 750 with the wireless communication function. As another example, the electronic device 800A illustrated in FIG. 21C has a function of transmitting information to the earphones 750 with the wireless communication function.

Alternatively, the electronic device may include earphone portions. The electronic device 700B illustrated in FIG. 21B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic device 800B illustrated in FIG. 21D includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. Alternatively, the electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (the electronic device 700A, the electronic device 700B, or the like) and the goggles-type device (the electronic device 800A, the electronic device 800B, or the like) are suitable as the electronic device of one embodiment of the present invention.

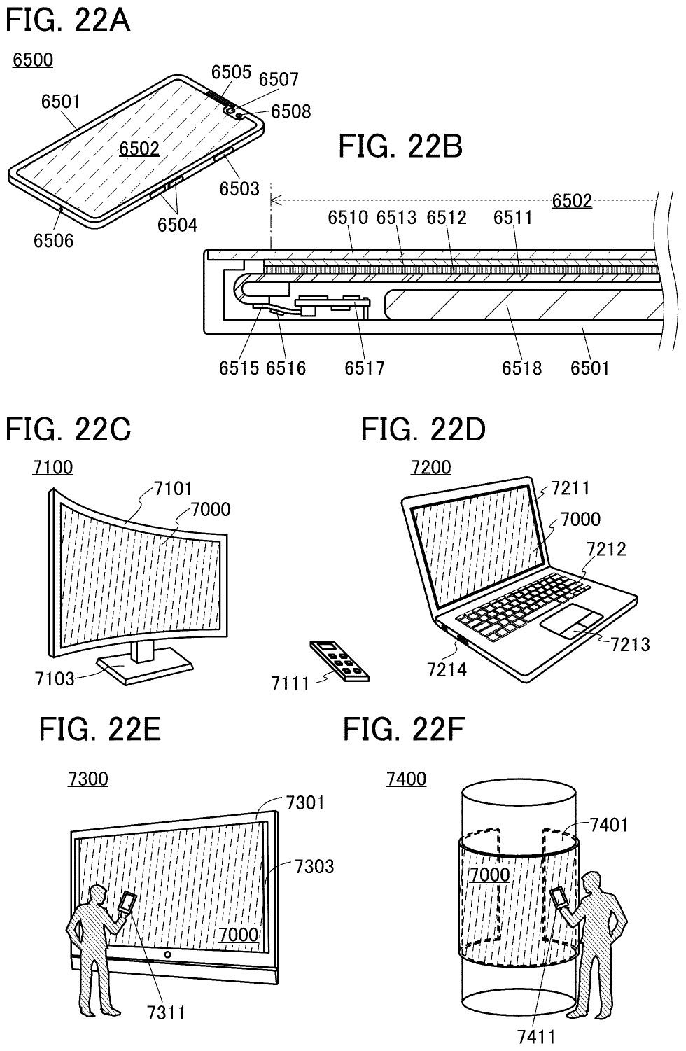

An electronic device 6500 illustrated in FIG. 22A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display panel of one embodiment of the present invention can be employed for the display portion 6502.

FIG. 22B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be employed for the display panel 6511. Thus, an extremely lightweight electronic device can be achieved. In addition, since the display panel 6511 is extremely thin, the battery 6518 with high capacity can be mounted while an increase in the thickness of the electronic device is suppressed. Moreover, part of the display panel 6511 is folded back so that a connection portion with the FPC 6515 is positioned on the back side of a pixel portion, whereby an electronic device with a narrow bezel can be achieved.

FIG. 22C illustrates an example of a television device. In a television device 7100, a display portion 7000 is incorporated in a housing 7101. Here, a structure in which the housing 7101 is supported by a stand 7103 is illustrated.

Operations of the television device 7100 illustrated in FIG. 22C can be performed with an operation switch provided in the housing 7101 and a separate remote control 7111. Alternatively, the display portion 7000 may include a touch sensor, and the television device 7100 may be operated by a touch on the display portion 7000 with a finger or the like. The remote control 7111 may include a display portion for displaying information output from the remote control 7111. With operation keys or a touch panel provided in the remote control 7111, channels and sound volume can be operated and a video displayed on the display portion 7000 can be operated.

Note that the television device 7100 includes a receiver, a modem, and the like. A general television broadcast can be received with the receiver. In addition, when the television device is connected to a communication network with or without wires via the modem, one-way (from a transmitter to a receiver) or two-way (between a transmitter and a receiver or between receivers, for example) information communication can be performed.

FIG. 22D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

FIG. 22E and FIG. 22F illustrate examples of digital signage.

Digital signage 7300 illustrated in FIG. 22E includes a housing 7301, the display portion 7000, a speaker 7303, and the like. Furthermore, the digital signage 7300 can include an LED lamp, an operation key (including a power switch or an operation switch), a connection terminal, a variety of sensors, a microphone, and the like.

FIG. 22F is digital signage 7400 attached to a cylindrical pillar 7401. The digital signage 7400 includes the display portion 7000 provided along a curved surface of the pillar 7401.

The larger display portion 7000 can increase the amount of information that can be provided at a time. In addition, the larger display portion 7000 attracts more attention, so that advertising effects can be increased, for example.

The use of a touch panel in the display portion 7000 is preferable because in addition to display of an image or a moving image on the display portion 7000, an intuitive operation by the user is possible. Moreover, for an application for providing information such as route information or traffic information, usability can be increased by an intuitive operation.

In addition, as illustrated in FIG. 22E and FIG. 22F, it is preferable that the digital signage 7300 or the digital signage 7400 can work with an information terminal device 7311 or an information terminal device 7411 such as a user's smartphone through wireless communication. For example, information of an advertisement displayed on the display portion 7000 can be displayed on a screen of the information terminal device 7311 or the information terminal device 7411. Furthermore, by the operation of the information terminal device 7311 or the information terminal device 7411, display on the display portion 7000 can be switched.

It is also possible to make the digital signage 7300 or the digital signage 7400 execute a game with the use of the screen of the information terminal device 7311 or the information terminal device 7411 as an operation means (a controller). Thus, an unspecified number of users can join in and enjoy the game concurrently.

The display panel of one embodiment of the present invention can be employed for the display portion 7000 illustrated in each of FIG. 22C to FIG. 22F.

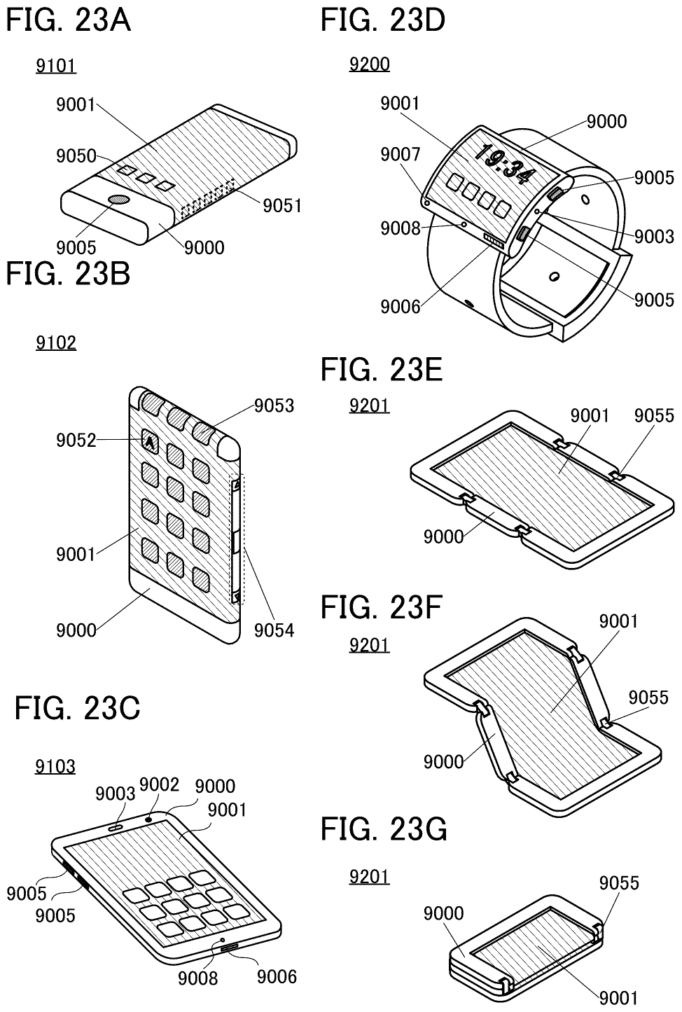

Electronic devices illustrated in FIG. 23A to FIG. 23G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, power, radiation, flow rate, humidity, a gradient, oscillation, odor, or infrared rays), a microphone 9008, and the like.

The electronic devices illustrated in FIG. 23A to FIG. 23G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a storage medium. Note that the functions of the electronic devices are not limited thereto, and the electronic devices can have a variety of functions. The electronic devices may each include a plurality of display portions. In addition, the electronic devices may each be provided with a camera or the like and have a function of taking a still image or a moving image and storing the taken image in a storage medium (an external storage medium or a storage medium incorporated in the camera), a function of displaying the taken image on the display portion, or the like.

The electronic devices illustrated in FIG. 23A to FIG. 23G are described in detail below.

FIG. 23A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. In addition, the portable information terminal 9101 can display characters and image information on its plurality of surfaces. FIG. 23A illustrates an example in which three icons 9050 are displayed. Furthermore, information 9051 indicated by dashed rectangles can be displayed on another surface of the display portion 9001. Examples of the information 9051 include notification of incoming e-mails, SNS, calls, and the like; the titles and senders of e-mails, SNS, and the like; dates; time; remaining battery; and radio field intensity. Alternatively, the icon 9050 or the like may be displayed at the position where the information 9051 is displayed.

FIG. 23B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is shown. For example, the user can check the information 9053 displayed such that it can be seen from above the portable information terminal 9102, with the portable information terminal 9102 put in a breast pocket of his/her clothes. The user can see display without taking out the portable information terminal 9102 from the pocket and determine whether to answer a call, for example.

FIG. 23C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on a front surface of the housing 9000; the operation keys 9005 as buttons for operations on a left side surface of the housing 9000; and the connection terminal 9006 on a bottom surface.

FIG. 23D is a perspective view illustrating a wristwatch-type portable information terminal 9200. For example, the portable information terminal 9200 can be used as a Smartwatch (registered trademark). In addition, a display surface of the display portion 9001 is provided to be curved, and display can be performed along the curved display surface. Furthermore, mutual communication between the portable information terminal 9200 and, for example, a headset capable of wireless communication enables hands-free calling. Moreover, with the connection terminal 9006, the portable information terminal 9200 can perform mutual data transmission with another information terminal and charging. Note that a charging operation may be performed by wireless power feeding.

FIG. 23E to FIG. 23G are perspective views illustrating a foldable portable information terminal 9201. In addition, FIG. 23E is a perspective view of an opened state of the portable information terminal 9201, FIG. 23G is a perspective view of a folded state thereof, and FIG. 23F is a perspective view of a state in the middle of change from one of FIG. 23E and FIG. 23G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. For example, the display portion 9001 can be bent with a radius of curvature greater than or equal to 0.1 mm and less than or equal to 150 mm.

At least part of this embodiment can be implemented in appropriate combination with the other embodiments described in this specification.

### REFERENCE NUMERALS

10a: transistor, 10: transistor, 11: substrate, 13: conductive layer, 14a: conductive layer, 14b: conductive layer, 14: conductive layer, 15: conductive layer, 20a: opening, 20b: opening, 20c: opening, 20d: opening, 20S: slit, 20: opening, 21a: semiconductor layer, 21b: semiconductor layer, 21: semiconductor layer, 22: insulating layer, 23a: conductive layer, 23b: conductive layer, 23: conductive layer, 24a: conductive layer, 24b: conductive layer, 24: conductive layer, 25A: conductive layer, 25a: conductive layer, 25b: conductive layer, 25: conductive layer, 28: insulating layer, 29a: insulating layer, 29b: insulating layer, 31: insulating layer, 32: insulating layer, 33: insulating layer, 34: insulating layer, 39: insulating layer

1. A semiconductor device comprising:
a first insulating layer;
a semiconductor layer;
a gate insulating layer;
a gate electrode;
a first electrode;
a second electrode; and
a first conductive layer,
wherein a side surface of the first insulating layer is over the first electrode,
wherein the second electrode is over the first insulating layer,
wherein the semiconductor layer is in contact with the first electrode, the side surface of the first insulating layer, and the second electrode,
wherein the gate insulating layer comprises a portion facing the side surface of the first insulating layer with the semiconductor layer interposed between the first insulating layer and the gate insulating layer,
wherein the gate electrode comprises a portion facing the side surface of the first insulating layer with the gate insulating layer and the semiconductor layer and interposed between the first insulating layer and the gate electrode,
wherein the first conductive layer is in contact with the gate electrode,
wherein the first conductive layer comprises a portion facing the side surface of the first insulating layer with the gate electrode, the gate insulating layer, and the semiconductor layer interposed between the first insulating layer and the first conductive layer, and
wherein the first conductive layer comprises a portion thicker than the gate electrode.

2. A semiconductor device comprising:
a first insulating layer;
a semiconductor layer;
a gate insulating layer;
a gate electrode;
a first electrode;
a second eel electrode; and
a first conductive layer,
wherein the first insulating layer comprises an opening,
wherein a side surface of the first insulating layer in the opening is over the first electrode,
wherein the second electrode is over the first insulating layer,
wherein the semiconductor layer, the gate insulating layer, the gate electrode, and the first conductive layer each comprises a portion inside the opening,
wherein the semiconductor layer is in contact with the first electrode, the side surface of the first insulating layer, and the second electrode,
wherein the gate insulating layer comprises a portion facing the side surface of the first insulating layer with the semiconductor layer interposed between the first insulating layer and the gate insulating layer,
wherein the gate electrode comprises a portion facing the side surface of the first insulating layer with the gate insulating layer and the semiconductor layer interposed between the first insulating layer and the gate electrode,
wherein the first conductive layer is in contact with the gate electrode,
wherein the first conductive layer comprises a portion facing the side surface of the first insulating layer with the gate electrode, the gate insulating layer, and the semiconductor layer interposed between the first insulating layer and the first conductive layer, and
wherein the first conductive layer comprises a portion thicker than the gate electrode.

3. A semiconductor device comprising:
a first insulating layer;
a semiconductor layer;
a gate insulating layer;
a gate electrode;
a first electrode;
a second electrode; and
a first conductive layer,
wherein the first insulating layer comprises a slit,
wherein a side surface of the first insulating layer in the slit is over the first electrode,
wherein the second electrode is over the first insulating layer,
wherein the semiconductor layer, the gate insulating layer, the gate electrode, and the first conductive layer each comprise a portion inside the slit,
wherein the semiconductor layer is in contact with the first electrode, the side surface of the first insulating layer, and the second electrode,
wherein the gate insulating layer comprises a portion facing the side surface of the first insulating layer with the semiconductor layer interposed between the first insulating layer and the gate insulating layer,
wherein the gate electrode comprises a portion facing the side surface of the first insulating layer with the gate insulating layer and the semiconductor layer interposed between the first insulating layer and the gate electrode,
wherein the first conductive layer is in contact with the gate electrode,
wherein the first conductive layer comprises a portion facing the side surface of the first insulating layer with the gate electrode, the gate insulating layer, and the semiconductor layer interposed between the first insulating layer and the first conductive layer, and
wherein the first conductive layer comprises a portion thicker than the gate electrode.

4. The semiconductor device according to claim 1, further comprising a second insulating layer,
wherein a top surface of the first conductive layer is level or substantially level with a top surface of the second insulating layer.

5. The semiconductor device according to claim 1,
wherein the semiconductor layer comprises a metal oxide, and
wherein the first electrode comprises a metal oxide having a composition different from that of the semiconductor layer.

6. The semiconductor device according to claim 5, further comprising a second conductive layer,
wherein the first electrode comprises a portion in contact with a top surface of the second conductive layer, and
wherein the second conductive layer comprises a metal or an alloy.

7. The semiconductor device according to claim 1,
wherein the semiconductor layer comprises a first portion in contact with a top surface of the first electrode, a second portion in contact with the side surface of the first insulating layer, and a third portion over the first insulating layer, and
wherein a thickness of the second portion is smaller than a thickness of the first portion and a thickness of the third portion.

8. The semiconductor device according to claim 1,
wherein an angle formed between the side surface of the first insulating layer and a top surface of the first electrode is greater than or equal to 90° and less than or equal to 120°.

9. The semiconductor device according to claim 1,
wherein the side surface of the first insulating layer comprises an uneven shape.

10. The semiconductor device according to claim 1,
wherein the semiconductor layer is in contact with a top surface of the second electrode,
wherein the semiconductor layer comprises a metal oxide, and
wherein the second electrode comprises a metal oxide having a composition different from that of the semiconductor layer.

11. The semiconductor device according to claim 10, further comprising a third conductive layer,
wherein the second electrode comprises a portion in contact with the third conductive layer, and
wherein the third conductive layer comprises a metal or an alloy.

12. The semiconductor device according to claim 2,
wherein the semiconductor layer comprises a metal oxide, and
wherein the first electrode comprises a metal oxide having a composition different from that of the semiconductor layer.

13. The semiconductor device according to claim 12, further comprising a second conductive layer,
wherein the first electrode comprises a portion in contact with a top surface of the second conductive layer, and
wherein the second conductive layer comprises a metal or an alloy.

14. The semiconductor device according to claim 2,
wherein the semiconductor layer comprises a first portion in contact with a top surface of the first electrode, a second portion in contact with the side surface of the first insulating layer, and a third portion over the first insulating layer, and
wherein a thickness of the second portion is smaller than a thickness of the first portion and a thickness of the third portion.

15. The semiconductor device according to claim 2,
wherein the semiconductor layer is in contact with a top surface of the second electrode,
wherein the semiconductor layer comprises a metal oxide, and
wherein the second electrode comprises a metal oxide having a composition different from that of the semiconductor layer.

16. The semiconductor device according to claim 3,
wherein the semiconductor layer comprises a metal oxide, and
wherein the first electrode comprises a metal oxide having a composition different from that of the semiconductor layer.

17. The semiconductor device according to claim 16, further comprising a second conductive layer,
wherein the first electrode comprises a portion in contact with a top surface of the second conductive layer, and
wherein the second conductive layer comprises a metal or an alloy.

18. The semiconductor device according to claim 3,
wherein the semiconductor layer comprises a first portion in contact with a top surface of the first electrode, a second portion in contact with the side surface of the first insulating layer, and a third portion over the first insulating layer, and
wherein a thickness of the second portion is smaller than a thickness of the first portion and a thickness of the third portion.

19. The semiconductor device according to claim 3,
wherein the semiconductor layer is in contact with a top surface of the second electrode,
wherein the semiconductor layer comprises a metal oxide, and
wherein the second electrode comprises a metal oxide having a composition different from that of the semiconductor layer.
